(19) United States
(12) Patent Application Publication
(10) Pub. No.: US 2026/0026222 A1
(43) Pub. Date: Jan. 22, 2026

(54) DISPLAY DEVICE AND METHOD FOR MANUFACTURING THE SAME, AND ELECTRONIC DEVICE FOR PROVIDING IMAGE

(71) Applicant: Samsung Display Co., Ltd., Yongin-si (KR)

(72) Inventors: Soo Hyun PARK, Yongin-si (KR); Seung Jun YU, Yongin-si (KR); Sarah LEE, Yongin-si (KR); Yung Bin CHUNG, Yongin-si (KR)

(73) Assignee: Samsung Display Co., Ltd., Yongin-si (KR)

(21) Appl. No.: 19/253,589

(22) Filed: Jun. 27, 2025

(30) Foreign Application Priority Data
Jul. 18, 2024 (KR) 10-2024-0095277
Oct. 14, 2024 (KR) 10-2024-0139424

(51) Int. Cl. H10K 59/131; H10K 59/12

(52) U.S. Cl. CPC H10K 59/131; H10K 59/1201

(57) ABSTRACT

A display device includes: a substrate; and a circuit layer on the substrate and including a semiconductor layer and conductive layers, wherein the circuit layer includes: a lower pattern included in one of the semiconductor layer and the conductive layers; a plurality of insulating layers on the lower pattern; a first contact hole penetrating the plurality of insulating layers and exposing a portion of the lower pattern; and a first conductive pattern on the plurality of insulating layers, filling the first contact hole, and including conductive particles.

### CROSS-REFERENCE TO RELATED APPLICATION

The present application claims priority to and the benefit of Korean Patent Application No. 10-2024-0095277, filed on Jul. 18, 2024, and Korean Patent Application No. 10-2024-0139424, filed on Oct. 14, 2024, in the Korean Intellectual Property Office, the entire disclosures of each of which are incorporated herein by reference.

### BACKGROUND

### 1. Field

Aspects of some embodiments of the present disclosure relate to a display device and a method for manufacturing the same, and an electronic device for providing an image.

### 2. Description of the Related Art

As the information society advances, the demand for display devices for displaying images has been increasing in various forms. In response to this, display devices of various types and sizes are being developed.

The above information disclosed in this Background section is only for enhancement of understanding of the background and therefore the information discussed in this Background section does not necessarily constitute prior art.

### SUMMARY

Aspects of some embodiments of the present disclosure include a display device and a method for manufacturing the same that can prevent or reduce instances of poor contact (or relatively improve contact), which may occur in contact holes, and relatively improve reliability, and an electronic device for providing or displaying images.

However, aspects of some embodiments of the present disclosure are not restricted to those set forth herein. The above and other aspects of some embodiments of the present disclosure will become more apparent to one of ordinary skill in the art to which the present disclosure pertains by referencing the detailed description of the present disclosure given below.

According to some embodiments of the present disclosure, a display device includes, a substrate, and a circuit layer on the substrate and including a semiconductor layer and conductive layers. According to some embodiments, the circuit layer may include a lower pattern included in one of the semiconductor layer and the conductive layers, a plurality of insulating layers on the lower pattern, a first contact hole penetrating the plurality of insulating layers and exposing a portion of the lower pattern, and a first conductive pattern on the plurality of insulating layers, filling the first contact hole, and including conductive particles.

According to some embodiments, the conductive particles may be metal particles.

According to some embodiments, a height of an edge portion of the first conductive pattern may be greater than a height of a central portion of the first conductive pattern.

According to some embodiments, an upper surface of the first conductive pattern may have a shape in which the height gradually increases from the central portion to the edge portion.

According to some embodiments, the first conductive pattern may completely fill the first contact hole.

According to some embodiments, an aspect ratio of the first contact hole may be 0.3 or greater.

According to some embodiments, the circuit layer may further include a second conductive pattern in a same layer as the first conductive pattern, and the first and second conductive patterns may include a same material.

According to some embodiments, the circuit layer may further include a second contact hole penetrating the plurality of insulating layers below the second conductive pattern and exposing a portion of a pattern below the second conductive pattern, and the second conductive pattern completely may fill the second contact hole.

According to some embodiments, the circuit layer may further include an electrode in a same layer as the first conductive pattern, and the first conductive pattern and the electrode may include different materials.

According to some embodiments, the electrode may include a metal layer.

According to some embodiments, the circuit layer may further include an electrode in a same layer as the first conductive pattern, and the first conductive pattern and the electrode may include a same material.

According to some embodiments, the circuit layer may further include at least one insulating layer on the first conductive pattern, an upper contact hole penetrating the at least one insulating layer and exposing a portion of the first conductive pattern, and an upper pattern on the at least one insulating layer and electrically connected to the first conductive pattern through the upper contact hole.

According to some embodiments, the first contact hole and the upper contact hole may overlap in a thickness direction of the substrate.

According to some embodiments, the display device may further include a light-emitting element layer on the circuit layer and including a light-emitting element electrically connected to a circuit element inside the circuit layer.

According to some embodiments of the present disclosure, there is provided a method for manufacturing a display device, including, forming a lower pattern including a semiconductor material or a conductive material on a substrate, and forming a plurality of insulating layers covering the lower pattern, forming a contact hole penetrating the plurality of insulating layers and exposing a portion of the lower pattern, and forming a conductive pattern filling the contact hole. According to some embodiments, the forming the conductive pattern may include, forming a mask pattern that exposes a first pattern area where the conductive pattern is to be formed and covers surroundings of the first pattern area, on the plurality of insulating layers and the contact hole, applying inorganic ink containing conductive particles to the plurality of insulating layers and the contact hole, and processing the inorganic ink into the conductive pattern.

According to some embodiments, the forming the mask pattern may include forming the mask pattern by a photolithography process using hydrophobic photoresist.

According to some embodiments, the applying the inorganic ink to the plurality of insulating layers and the contact hole may include applying the inorganic ink by an inkjet printing method or a slit coating method and completely filling the contact hole with the inorganic ink.

According to some embodiments, the method may further include removing the mask pattern after the forming the conductive pattern.

According to some embodiments, the mask pattern may further expose a second pattern area spaced apart from the first pattern area and may cover surroundings of the first and second pattern areas.

According to some embodiments, the inorganic ink may also be applied to the second pattern area, and in the processing the inorganic ink into the conductive pattern, the inorganic ink applied to the second pattern area may be processed into an electrode in a same layer as the conductive pattern.

According to some embodiments of the present disclosure, there is provided an electronic device for providing an image, including a display device, the display device including a substrate, and a circuit layer on the substrate and including a semiconductor layer and conductive layers. According to some embodiments, the circuit layer may include a lower pattern included in one of the semiconductor layer and the conductive layers, a plurality of insulating layers on the lower pattern, a first contact hole penetrating the plurality of insulating layers and exposing a portion of the lower pattern, and a first conductive pattern on the plurality of insulating layers, filling the first contact hole, and including conductive particles.

According to some embodiments, a conductive pattern that stably fills a contact hole can be formed using inorganic ink containing conductive particles. As a result, potential contact defects in the contact hole can be prevented or reduced, and the reliability of the display device can be relatively improved.

According to some embodiments of the present disclosure, even in a high- resolution display device that includes a narrow and deep contact hole, the contact hole can be stably filled with a conductive pattern formed using inorganic ink, thereby relatively improving the contact quality. Additionally, another contact hole can be directly on the conductive pattern to overlap with the contact hole penetrated by the conductive pattern. This allows for the optimization or relative improvement of the design structure of the high-resolution display device and relatively enhances its reliability.

It should be noted that the characteristics of embodiments according to the present disclosure are not limited to those described above, and other characteristics of embodiments according to the present disclosure will be apparent from the following description.

### BRIEF DESCRIPTION OF THE DRAWINGS

The above and other aspects and features of some embodiments of the present disclosure will become more apparent by describing in more detail aspects of some embodiments thereof with reference to the attached drawings, in which:

FIG. 1 is a perspective view illustrating a display device according to some embodiments;

FIG. 2 is an equivalent circuit diagram illustrating a pixel according to some embodiments;

FIG. 3 is a cross-sectional view illustrating a display device according to some embodiments;

FIG. 4 is a cross-sectional view illustrating a conductive pattern according to some embodiments;

FIG. 5 is a cross-sectional view illustrating a conductive pattern according to some embodiments;

FIG. 6 is a cross-sectional view illustrating a conductive pattern according to some embodiments;

FIG. 7 is a cross-sectional view illustrating a conductive pattern according to some embodiments;

FIGS. 8 through 15 are cross-sectional views illustrating a method for manufacturing a display device according to some embodiments;

FIGS. 16 and 17 are cross-sectional views illustrating a method for manufacturing a display device according to some embodiments;

FIGS. 18 and 19 are cross-sectional views illustrating methods for manufacturing a display device according to some embodiments;

FIGS. 20 through 23 are cross-sectional views illustrating a method for manufacturing a display device according to some embodiments;

FIG. 24 is a perspective view illustrating a head-mounted display (HMD) device according to some embodiments;

FIG. 25 is an exploded perspective view illustrating the HMD device of FIG. 24; and

FIG. 26 is a perspective view illustrating an HMD device according to some embodiments.

### DETAILED DESCRIPTION

Aspects of some embodiments of the present disclosure will now be described more fully hereinafter with reference to the accompanying drawings, in which aspects of some embodiments of the present disclosure are shown. Embodiments according to the present disclosure may, however, be embodied in different forms and should not be construed as being limited to the embodiments set forth herein. Rather, these embodiments are provided so that this disclosure will be thorough and complete, and will more fully convey the scope of embodiments according to the present disclosure to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

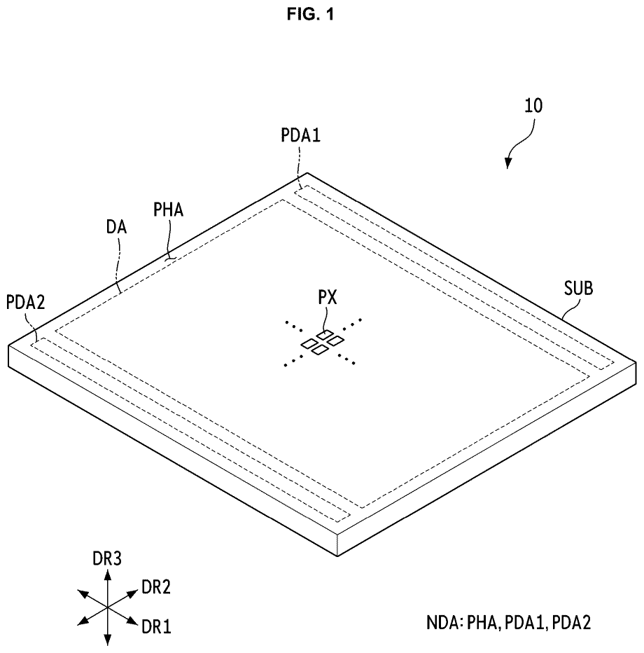

FIG. 1 is a perspective view illustrating a display device according to some embodiments.

Referring to FIG. 1, a display device 10 is a device for displaying moving or still images and may be used as a display screen in various electronic devices. For example, the display device 10 may be used as the display screen in portable electronic devices such as mobile phones, smartphones, tablet personal computers (PCs), smartwatches, watch phones, mobile communication terminals, electronic notebooks, e-book readers, portable multimedia players (PMPs), navigation systems, ultra mobile PCs (UMPCs), and other similar devices. In addition, the display device 10 may also be included in other electronic devices, such as televisions, laptops, monitors, billboards, Internet of Things (IOT) devices, and similar electronic devices, serving as their display screen. Furthermore, the display device 10 may be included in other electronic devices, such as virtual reality (VR) or augmented reality (AR) devices.

According to some embodiments, the display device 10 may be a light- emitting display device that includes light-emitting elements. For example, the display device 10 may be an organic light-emitting display device that includes organic light- emitting diodes (OLEDs), a quantum dot light-emitting display device that includes a quantum dot light-emitting layer, an inorganic light-emitting display device that includes an inorganic semiconductor, or a micro or nano light-emitting diode display device that includes micro or nano light-emitting diodes (micro LEDs or nano LEDs). However, the present disclosure is not limited to this. For example, the display device 10 may also be other types of display devices, aside from light-emitting display devices.

Embodiments where the display device 10 is an organic light-emitting display device will hereinafter be described. However, the display device 10 is not limited to an organic light-emitting display device, and the technical features of the embodiments to be described later may also be applicable to other types of display devices.

The display device 10 may include a substrate SUB and pixels PX arranged on the substrate SUB.

The substrate SUB may be a base layer for manufacturing or providing the display device 10. The substrate SUB may have a rectangular planar shape on a plane defined by a first direction DR1 and a second direction DR2, but embodiments according to the present disclosure are not limited thereto. For example, the substrate SUB may also have other planar shapes, such as a polygonal, circular, elliptical, or irregular shape.

In FIG. 1, the first direction DR1 may indicate the horizontal direction (or vertical direction) of the substrate SUB (or the display device 10), and the second direction DR2 may indicate the vertical direction (or horizontal direction) of the substrate SUB. A third direction DR3 may indicate the thickness direction or height direction of the substrate SUB.

The substrate SUB and the display device 10 that includes the substrate SUB may include a display area DA and a non-display area NDA. The display area DA may be an area where images are displayed, and the non-display area NDA may be the remaining area excluding the display area DA.

The display area DA may be an area where the pixels PX are arranged. For example, the display area DA may include the pixels PX and wiring (or portions of the wiring) connected to the pixels PX. Here, the term “connected” or “connection” may include both electrical connections and/or physical connections.

The non-display area NDA may be arranged around (e.g., in a periphery or outside a footprint of) the display area DA. According to some embodiments, the non- display area NDA may include a first pad area PDA1, a second pad area PDA2, and a peripheral area PHA. The non-display area NDA may include wiring connected to the pixels PX (e.g., portions of the wiring extending from the display area DA to the non- display area NDA) and pads. According to some embodiments, the non-display area NDA may further include a driving circuit area where at least portions of driving circuitry connected to the pixels PX are arranged.

In FIG. 1, the display device 10 is illustrated as including the first and second pad areas PDA1 and PDA2 on different sides (for example, the upper and lower sides) of the display area DA. However, the number or location of the first and second pad areas PDA1 and PDA2 is not particularly limited. For example, the display device 10 may include only one of the first and second pad areas PDA1 and PDA2, or may include three or more pad areas.

The first and second pad areas PDA1 and PDA2 may each include pads that are connected to an external circuit board. Through these pads, driving signals and driving voltages for driving the pixels PX may be supplied from the circuit board to the display device 10.

The peripheral area PHA may be the remaining area of the non-display area NDA excluding the first and second pad areas PDA1 and PDA2. The peripheral area PHA may surround the display area DA. The peripheral area PHA may or may not include the driving circuit area.

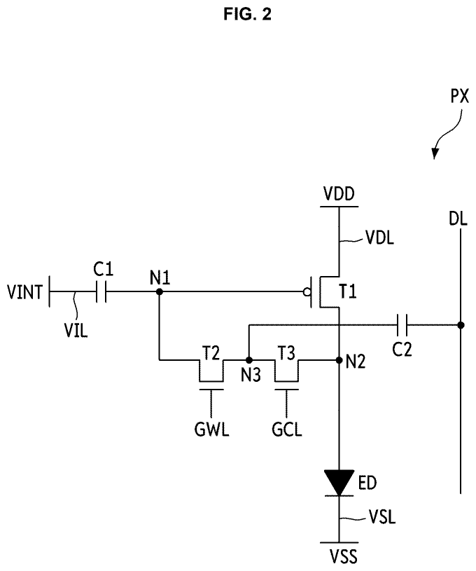

FIG. 2 is an equivalent circuit diagram illustrating a pixel according to some embodiments. Although FIG. 2 illustrates various components in a pixel according to some embodiments, embodiments according to the present disclosure are not limited thereto, and according to various embodiments, the pixel may include additional components or fewer components, without departing from the spirit and scope of embodiments according to the present disclosure.

Referring to FIG. 2, a pixel PX may be connected to signal lines including a first scan line GWL, a second scan line GCL, and a data line DL, and to power lines including a first voltage line VDL, a second voltage line VSL, and an initialization voltage line (or an initialization signal line) VIL. The types or numbers of signal lines and power lines connected to the pixel PX may vary depending on the type or structure of the pixel PX.

The first scan line GWL and the second scan line GCL may be connected between a scan driving circuit and the pixel PX. The first scan line GWL transmits a first scan signal output from the scan driving circuit to the pixel PX. According to some embodiments, the first scan line GWL may be a write scan line, and the first scan signal may be a write scan signal. The second scan line GCL transmits a second scan signal output from the scan driving circuit to the pixel PX. According to some embodiments, the second scan line GCL may be a control scan line, and the second scan signal may be a control scan signal. The scan driving circuit may be located on the substrate SUB, or on a circuit board connected to the display device 10 through signal pads (e.g., scan pads) arranged in at least one of the first pad area PDA1 or the second pad area PDA2.

The data line DL may be connected between a data driving circuit and the pixel PX. The data line DL transmits a data voltage output from the data driving circuit to the pixel PX. The data driving circuit may be located on the substrate SUB, or on a circuit board connected to the display device 10 through signal pads (e.g., data pads) arranged in at least one of the first pad area PDA1 or the second pad area PDA2.

The first voltage line VDL and the second voltage line VSL may be connected between a power supply circuit and the pixel PX. The first voltage line VDL and the second voltage line VSL transmit a first driving voltage VDD and a second driving voltage VSS output from the power supply circuit to the pixel PX. According to some embodiments, the first driving voltage VDD may be a high-potential pixel voltage, and the second driving voltage VSS may be a low-potential pixel voltage. According to some embodiments, the power supply circuit may be arranged on a circuit board connected to the display device 10 through power pads arranged in at least one of the first pad area PDA1 or the second pad area PDA2.

The initialization voltage line VIL may be connected between the power supply circuit or the scan driving circuit and the pixel PX. The initialization voltage line VIL transmits an initialization voltage VINT output from the power supply circuit or the scan driving circuit to the pixel PX.

The pixel PX may include a light-emitting element ED and a pixel circuit electrically connected to the light-emitting element ED.

The light-emitting element ED may be connected between the pixel circuit and the second voltage line VSL. For example, a first electrode (e.g., the anode) of the light-emitting element ED may be connected to the pixel circuit via a second node N2, and a second electrode (e.g., the cathode) of the light-emitting element ED may be connected to the second voltage line VSL.

The light-emitting element ED serves as a light source of the pixel PX and may emit light in response to a driving current supplied from the pixel circuit. According to some embodiments, the light-emitting element ED may be an OLED, but the present disclosure is not limited thereto. Alternatively, for example, the light- emitting element ED may be an inorganic light-emitting element, a quantum dot light- emitting element, or another type of light-emitting element.

The pixel circuit may be connected between the first voltage line VDL and the light-emitting element ED. In addition, the pixel circuit may also be connected to the first scan line GWL, the second scan line GCL, the data line DL, and the initialization voltage line VIL.

The pixel circuit may include circuit elements such as transistors and capacitors. The pixel circuit may be configured to enable the pixel PX to emit light at a uniform brightness corresponding to a grayscale data voltage, and thus may include multiple transistors and at least one capacitor. According to some embodiments, the pixel circuit may include first, second, and third transistors T1, T2, and T3 and first and second capacitors C1 and C2. The type or structure of the pixel circuit may vary according to some embodiments.

According to some embodiments, the pixel circuit may include P-type transistors and N-type transistors. For example, the first transistor T1 may be a P-type transistor, and the second transistor T2 and the third transistor T3 may be N-type transistors. According to some embodiments, P-and N-type transistors may include active layers formed from different materials. For example, the active layer of a P-type transistor may include polysilicon, and the active layer of an N-type transistor may include an oxide semiconductor.

However, the present disclosure is not limited to this. Alternatively, for example, the first, second, and third transistors T1, T2, and T3 may be transistors of the same type (e.g., all P-or N-type transistors).

The first, second, and third transistors T1, T2, and T3 may each include a gate electrode, a source electrode (or a source region functioning as the source electrode), and a drain electrode (or a drain region functioning as the drain electrode). The source electrodes and drain electrodes of the first, second, and third transistors T1, T2, and T3 may be first electrodes and second electrodes other than gate electrodes. Depending on the voltage applied to the two terminals of each of the first, second, and third transistors T1, T2, and T3, and the type of the corresponding transistor (e.g., P-type or N-type), one of the first and second electrodes may function as the source electrode, and the other may function as the drain electrode.

The gate electrode of the first transistor T1 may be connected to a first node N1, the source electrode of the first transistor T1 may be connected to the first voltage line VDL, and the drain electrode of the first transistor T1 may be connected to the second node N2. The second node N2 may be the node to which the first electrode (e.g., the anode) of the light-emitting element ED is connected. The first transistor T1 may control the driving current flowing to the light-emitting element ED according to the voltage at the first node N1.

The gate electrode of the second transistor T2 may be connected to the first scan line GWL, the source electrode of the second transistor T2 may be connected to the first node N1, and the drain electrode of the second transistor T2 may be connected to a third node N3. The second transistor T2 may be turned on by the first scan signal, which is a gate-on voltage applied to the first scan line GWL, thereby electrically connecting the first node N1 and the third node N3.

The first node N1 may be connected to the first electrode of the first capacitor C1. The voltage at the first node N1 may be initialized by the initialization voltage VINT applied to the initialization voltage line VIL, which is connected to the second electrode of the first capacitor C1.

The third node N3 may be connected to the first electrode of the second capacitor C2. The voltage at the third node N3 may change to a voltage corresponding to the data voltage applied to the data line DL, which is connected to the second electrode of the second capacitor C2.

The gate electrode of the third transistor T3 may be connected to the second scan line GCL, the source electrode of the third transistor T3 may be connected to the third node N3, and the drain electrode of the third transistor T3 may be connected to the second node N2. The third transistor T3 may be turned on by the second scan signal, which is a gate-on voltage applied to the second scan line GCL, thereby electrically connecting the third node N3 and the second node N2.

The first capacitor C1 may be connected between the first node N1 and the initialization voltage line VIL. For example, the first electrode of the first capacitor C1 may be connected to the first node N1, and the second electrode of the first capacitor C1 may be connected to the initialization voltage line VIL, thereby maintaining the potential difference between the first node N1 and the initialization voltage line VIL. The voltage at the first node N1 may be initialized by the initialization voltage VINT applied to the initialization voltage line VIL.

The second capacitor C2 may be connected between the third node N3 and the data line DL. For example, the first electrode of the second capacitor C2 may be connected to the third node N3, and the second electrode of the second capacitor C2 may be connected to the data line DL, thereby maintaining the potential difference between the third node N3 and the data line DL. The voltage at the third node N3 may change to a voltage corresponding to the data voltage applied to the data line DL.

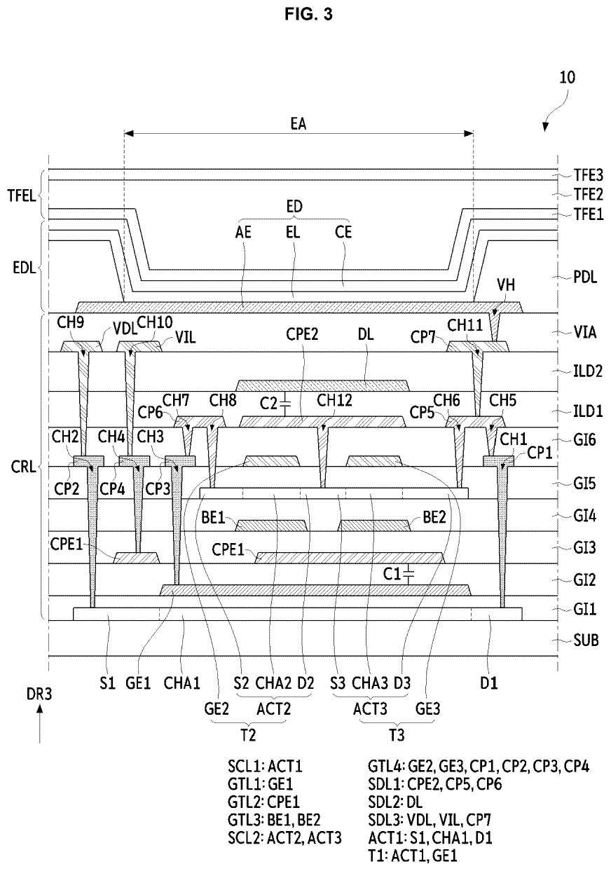

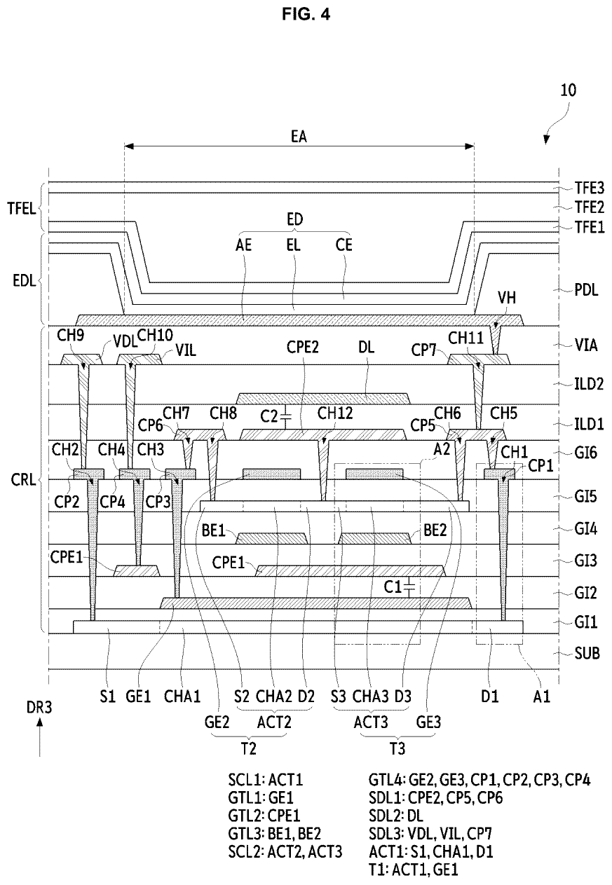

FIG. 3 is a cross-sectional view illustrating aspects the display device according to some embodiments. FIG. 4 is another cross-sectional view illustrating aspects of the display device according to some embodiments. For example, FIGS. 3 and 4 are schematic cross-sectional views of a portion of the display device 10 (e.g., one pixel region located in the display area DA) where a pixel PX is arranged, and illustrate different embodiments of the patterns of the fourth conductive layer GTL4.

Referring to FIGS. 3 and 4, the display device 10 may include a substrate SUB and a circuit layer CRL arranged on the substrate SUB. According to some embodiments, the display device 10 may be a light-emitting display device that includes a light-emitting element ED, and may further include a light-emitting element layer EDL and an encapsulation layer TFEL. According to some embodiments, the circuit layer CRL, the light-emitting element layer EDL, and the encapsulation layer TFEL may be sequentially arranged on the substrate SUB along the third direction DR3.

FIGS. 3 and 4 illustrate a structure where a first transistor T1 of the circuit layer CRL is directly located on the substrate SUB, but the present disclosure is not limited thereto. Alternatively, for example, a buffer layer (or barrier layer) may be formed on the substrate SUB, and the circuit layer CRL may be located on the buffer layer.

The substrate SUB may be a base layer for forming the display device 10. For example, the substrate SUB may serve as a support for a display panel that includes the pixel PX.

The substrate SUB may be a substrate that includes an insulating material such as glass and has rigid characteristics, but embodiments according to the present disclosure are not limited thereto. For example, the substrate SUB may include an insulating material such as a polymer resin and may be a flexible substrate capable of bending, folding, or rolling. According to some embodiments, the substrate SUB may be a semiconductor substrate, and the substrate SUB and the pixel circuit of the pixel PX may be formed as a semiconductor circuit substrate that includes a complementary metal-oxide semiconductor (CMOS) circuit formed using semiconductor processing.

The circuit layer CRL may be located on the substrate SUB (or on the buffer layer). The circuit layer CRL may include circuit elements included in the pixel PX (e.g., circuit elements included in the pixel circuit) and wiring connected to the pixel PX. For example, the circuit layer CRL may include first, second, and third transistors T1, T2, and T3, first and second capacitors C1 and C2, a first scan line GWL, a second scan line GCL, a data line DL, a first voltage line VDL, a second voltage line VSL, and an initialization voltage line VIL, as illustrated in FIG. 2.

The circuit layer CRL may include at least one semiconductor layer, a plurality of conductive layers, and a plurality of insulating layers located on the substrate SUB (or on the buffer layer). The semiconductor layer of the circuit layer CRL may include the active layers of the transistors located within the circuit layer CRL. The conductive layers of the circuit layer CRL may include conductive patterns included in or connected to the circuit elements (e.g., transistors and capacitors) located within the circuit layer CRL. These conductive patterns may include the electrodes of the circuit elements, connection patterns connected to the circuit elements, and/or wiring. The insulating layers of the circuit layer CRL may be located between the semiconductor layer and the conductive layers.

According to some embodiments, the pixel PX may include at least two types of transistors, and the circuit layer CRL may include a plurality of semiconductor layers. For example, the circuit layer CRL may include a first semiconductor layer SCL1 that includes a first active layer ACT1 of the first transistor T1 and a second semiconductor layer SCL2 that includes a second active layer ACT2 of the second transistor T2 and a third active layer ACT3 of the third transistor T3. The first semiconductor layer SCL1 and the second semiconductor layer SCL2 may be located on different layers on the substrate SUB. Therefore, the integration level of the circuit layer CRL can be enhanced, and the design of the circuit layer CRL can be optimized or improved. For example, in a high-resolution display device that includes smaller-size (or area) pixels PX, the circuit elements of the pixels PX may be appropriately arranged within limited pixel regions.

According to some embodiments, the conductive layers of the circuit layer CRL may include a first conductive layer GTL1, a second conductive layer GTL2, a third conductive layer GTL3, a fourth conductive layer GTL4, a fifth conductive layer SDL1, a sixth conductive layer SDL2, and a seventh conductive layer SDL3. The first conductive layer GTL1, the second conductive layer GTL2, the third conductive layer GTL3, the fourth conductive layer GTL4, the fifth conductive layer SDL1, the sixth conductive layer SDL2, and the seventh conductive layer SDL3 may correspond to a first gate conductive layer, a second gate conductive layer, a third gate conductive layer, a fourth gate conductive layer, a first source-drain conductive layer (or first data conductive layer), a second source-drain conductive layer (or second data conductive layer), and a third source-drain conductive layer (or third data conductive layer), respectively, but embodiments according to the present disclosure are not limited thereto.

According to some embodiments, the insulating layers of the circuit layer CRL may include a first insulating layer GI1, a second insulating layer GI2, a third insulating layer GI3, a fourth insulating layer GI4, a fifth insulating layer GI5, a sixth insulating layer GI6, a seventh insulating layer ILD1, an eighth insulating layer ILD2, and a ninth insulating layer VIA, which are sequentially located on the substrate SUB along the third direction DR3. The first insulating layer GI1, the second insulating layer GI2, the third insulating layer GI3, the fourth insulating layer GI4, the fifth insulating layer GI5, the sixth insulating layer GI6, the seventh insulating layer ILD1, the eighth insulating layer ILD2, and the ninth insulating layer VIA may correspond to a first gate insulating layer, a second gate insulating layer, a third gate insulating layer, a fourth gate insulating layer, a fifth gate insulating layer, a sixth gate insulating layer, a first interlayer insulating layer, a second interlayer insulating layer, and a planarization layer (or via layer), respectively, but embodiments according to the present disclosure are not limited thereto.

The structure of the circuit layer CRL may vary according to some embodiments. For example, the numbers, types, and/or locations of the semiconductor layer(s), conductive layers, and insulating layers included in the circuit layer CRL, and the numbers, types, and/or shapes of the patterns included in the semiconductor layer(s), conductive layers, and insulating layers, may be variously modified depending on the design structure of the pixel circuit and wiring.

The first semiconductor layer SCL1 may be located on the substrate SUB (or the buffer layer). The first semiconductor layer SCL1 may include semiconductor patterns that contain a semiconductor material (e.g., polysilicon, amorphous silicon, oxide semiconductor, or other semiconductor materials). According to some embodiments, the semiconductor patterns of the first semiconductor layer SCL1 may include polysilicon. According to some embodiments, the first semiconductor layer SCL1 may include the first active layer ACT1 of the first transistor T1 of the pixel PX.

The first active layer ACT1 may include a first channel region CHA1, a first source region S1, and a first drain region D1. The first channel region CHA1 may overlap with a first gate electrode GE1 of the first transistor T1. The first channel region CHA1 may form a channel in response to the voltage applied to the first gate electrode GE1. The first source region S1 and the first drain region D1 may be located on both sides of the first channel region CHA1. The first source region S1 and the first drain region D1 may have higher conductivity compared to the first channel region CHA1. For example, the carrier concentration of the first source region S1 and the first drain region D1 may be higher than the carrier concentration of the first channel region CHA1.

According to some embodiments, the first source region S1 may be electrically connected to the first voltage line VDL through a second conductive pattern CP2 (or the first source electrode of the first transistor T1). The first drain region D1 may be electrically connected to a first electrode AE of a light-emitting element ED and the third drain region D3 of the third transistor T3 through at least one conductive pattern, including a first conductive pattern CP1 (or the first drain electrode of the first transistor T1).

The first insulating layer GI1 may be located on the substrate SUB and the first semiconductor layer SCL1 and may cover the semiconductor patterns of the first semiconductor layer SCL1. For example, the first insulating layer GI1 may cover the first active layer ACT1.

The first conductive layer GTL1 may be located on the first insulating layer GI1. The first conductive layer GTL1 may include conductive patterns that contain a conductive material. For example, the first conductive layer GTL1 may include the first gate electrode GE1 of the first transistor T1 of the pixel PX. According to some embodiments, the first gate electrode GE1 may be integrally formed with the first electrode of the first capacitor C1. For example, the first gate electrode GE1 may overlap with a first capacitor electrode CPE1, and the first capacitor C1 may be formed by the first gate electrode GE1 and the first capacitor electrode CPE1. The first gate electrode GE1 and the first capacitor electrode CPE1 may form the first and second electrodes, respectively, of the first capacitor C1.

The second insulating layer GI2 may be located on the first insulating layer GI1 and the first conductive layer GTL1 and may cover the conductive patterns of the first conductive layer GTL1. For example, the second insulating layer GI2 may cover the first gate electrode GE1.

The second conductive layer GTL2 may be located on the second insulating layer GI2. The second conductive layer GTL2 may include conductive patterns that contain a conductive material. For example, the second conductive layer GTL2 may include the first capacitor electrode CPE1, which overlaps with the first gate electrode GE1 of the pixel PX. The first capacitor electrode CPE1, which is illustrated in FIGS. 3 and 4 as two separate patterns, may be a single electrode when viewed in a plan view.

The third insulating layer GI3 may be located on the second insulating layer GI2 and the second conductive layer GTL2, and may cover the conductive patterns of the second conductive layer GTL2. For example, the third insulating layer GI3 may cover the first capacitor electrode CPE1.

The third conductive layer GTL3 may be located on the third insulating layer GI3. The third conductive layer GTL3 may include conductive patterns that contain a conductive material. For example, the third conductive layer GTL3 may include a first bottom electrode BE1 and a second bottom electrode BE2, which overlap with the second active layer ACT2 of the second transistor T2 and the third active layer ACT3 of the third transistor T3 of the pixel PX. The first bottom electrode BE1 may overlap with the second channel region CHA2 of the second active layer ACT2, and the second bottom electrode BE2 may overlap with the third channel region CHA3 of the third active layer ACT3. According to some embodiments, the first bottom electrode BE1 may be electrically connected to a second gate electrode GE2 of the second transistor T2, but embodiments according to the present disclosure are not limited thereto. According to some embodiments, the second bottom electrode BE2 may be electrically connected to a third gate electrode GE3 of the third transistor T3, but embodiments according to the present disclosure are not limited thereto.

The fourth insulating layer GI4 may be located on the third insulating layer GI3 and the third conductive layer GTL3, and may cover the conductive patterns of the third conductive layer GTL3. For example, the fourth insulating layer GI4 may cover the first bottom electrode BE1 and the second bottom electrode BE2.

The second semiconductor layer SCL2 may be located on the fourth insulating layer GI4. The second semiconductor layer SCL2 may include semiconductor patterns that contain a semiconductor material (e.g., polysilicon, amorphous silicon, oxide semiconductor, or other semiconductor materials). According to some embodiments, the semiconductor patterns of the second semiconductor layer SCL2 may include an oxide semiconductor. According to some embodiments, the second semiconductor layer SCL2 may include the second active layer ACT2 and the third active layer ACT3 included in the second transistor T2 and the third transistor T3, respectively, of the pixel PX. According to some embodiments, the second active layer ACT2 and the third active layer ACT3 may be integrally formed. For example, the second drain region D2 and the third source region S3 may be a single integral region.

The second active layer ACT2 may include a second channel region CHA2, a second source region S2, and a second drain region D2. The second channel region CHA2 may overlap with the second gate electrode GE2 of the second transistor T2. The second channel region CHA2 may form a channel in response to the voltage applied to the second gate electrode GE2. The second source region S2 and the second drain region D2 may be located on both sides of the second channel region CHA2. The second source region S2 and the second drain region D2 may have higher conductivity than the second channel region CHA2.

The third active layer ACT3 may include a third channel region CHA3, a third source region S3, and a third drain region D3. The third channel region CHA3 may overlap with the third gate electrode GE3 of the third transistor T3. The third channel region CHA3 may form a channel in response to the voltage applied to the third gate electrode GE3. The third source region S3 and the third drain region D3 may be located on both sides of the third channel region CHA3. The third source region S3 and the third drain region D3 may have higher conductivity than the third channel region CHA3.

According to some embodiments, the second source region S2 may be electrically connected to the first gate electrode GE1 through a sixth conductive pattern CP6 (or the second source electrode of the second transistor T2). The second drain region D2 may be integrated with the third source region S3. The second drain region D2 and the third source region S3 may be electrically connected to a second capacitor electrode CPE2 (or the second drain electrode of the second transistor T2 and the third source electrode of the third transistor T3). The third drain region D3 may be electrically connected to the first drain region D1 and the first electrode AE of the light- emitting element ED through at least one conductive pattern, including a fifth conductive pattern CP5 (or the third drain electrode of the third transistor T3).

The fifth insulating layer GI5 may be located on the fourth insulating layer GI4 and the second semiconductor layer SCL2, and may cover the semiconductor patterns of the second semiconductor layer SCL2. For example, the fifth insulating layer GI5 may cover the second active layer ACT2 and the third active layer ACT3.

The fourth conductive layer GTL4 may be located on the fifth insulating layer GI5. The fourth conductive layer GTL4 may include conductive patterns that contain a conductive material. For example, the fourth conductive layer GTL4 may include the second gate electrode GE2 and the third gate electrode GE3 included in the second transistor T2 and the third transistor T3, respectively, of the pixel PX. The second gate electrode GE2 may be electrically connected to the first scan line GWL in FIG. 2. For example, the second gate electrode GE2 and the first scan line GWL may be integrally formed, but embodiments according to the present disclosure are not limited thereto. The third gate electrode GE3 may be electrically connected to the second scan line GCL in FIG. 2. For example, the third gate electrode GE3 and the second scan line GCL may be integrally formed, but the present disclosure is not limited thereto.

According to some embodiments, the fourth conductive layer GTL4 may further include at least one conductive pattern that forms another electrode of at least one circuit element included in the pixel PX or a connection pattern electrically connected to the at least one circuit element. For example, the fourth conductive layer GTL4 may further include the first, second, third, and fourth conductive patterns CP1, CP2, CP3, and CP4 of the pixel PX.

The first conductive pattern CP1 may be electrically connected to a region of the first active layer ACT1 through multiple insulating layers located between the first semiconductor layer SCL1 and the fourth conductive layer GTL4. For example, the first conductive pattern CP1 may be electrically connected to the first drain region D1 through a first contact hole CH1, which is formed in the first, second, third, fourth, and fifth insulating layers GI1, GI2, GI3, GI4, and GI5 to expose a portion of the first drain region D1. For example, the first conductive pattern CP1 may be in direct contact with the first drain region D1 exposed by the first contact hole CH1. According to some embodiments, the first conductive pattern CP1 may be the drain electrode of the first transistor T1 and may be considered as part of the first transistor T1.

The second conductive pattern CP2 may be electrically connected to another region of the first active layer ACT1 through multiple insulating layers located between the first semiconductor layer SCL1 and the fourth conductive layer GTL4. For example, the second conductive pattern CP2 may be electrically connected to the first source region S1 through a second contact hole CH2, which is formed in the first, second, third, fourth, and fifth insulating layers GI1, GI2, GI3, GI4, and GI5 to expose a portion of the first source region S1. According to some embodiments, the second conductive pattern CP2 may be the source electrode of the first transistor T1 and may be considered as part of the first transistor T1.

The third conductive pattern CP3 may be electrically connected to the first gate electrode GE1 through multiple insulating layers located between the first conductive layer GTL1 and the fourth conductive layer GTL4. For example, the third conductive pattern CP3 may be electrically connected to the first gate electrode GE1 through a third contact hole CH3, which is formed in the second, third, fourth, and fifth insulating layers GI2, GI3, GI4, and GI5 to expose a portion of the first gate electrode GE1. According to some embodiments, the third conductive pattern CP3 may be a connection pattern that forms a first node N1.

The fourth conductive pattern CP4 may be electrically connected to the first capacitor electrode CPE1 through multiple insulating layers located between the second conductive layer GTL2 and the fourth conductive layer GTL4. For example, the fourth conductive pattern CP4 may be electrically connected to the first capacitor electrode CPE1 through a fourth contact hole CH4, which is formed in the third, fourth, and fifth insulating layers GI3, GI4, and GI5 to expose a portion of the first capacitor electrode CPE1. According to some embodiments, the fourth conductive pattern CP4 may be a connection pattern that connects the first capacitor electrode CPE1 and the initialization voltage line VIL.

The sixth insulating layer G16 may be located on the fifth insulating layer GI5 and the fourth conductive layer GTL4, and may cover the conductive patterns of the fourth conductive layer GTL4. For example, the sixth insulating layer GI6 may cover the second and third gate electrodes GE2 and GE3 and the first, second, third, and fourth conductive patterns CP1, CP2, CP3, and CP4.

The fifth conductive layer SDL1 may be located on the sixth insulating layer G16. The fifth conductive layer SDL1 may include conductive patterns that contain a conductive material. For example, the fifth conductive layer SDL1 may include the second capacitor electrode CPE2 of the pixel PX. The second capacitor electrode CPE2 may overlap with the data line DL connected to the pixel PX (or the second electrode of the second capacitor C2, which is electrically connected to the data line DL), and the second capacitor C2 may be formed by the second capacitor electrode CPE2 and the data line DL. The second capacitor electrode CPE2 and the data line DL may form the first and second electrodes, respectively, of the second capacitor C2.

The second capacitor electrode CPE2 may be electrically connected to regions of the second and third active layers ACT2 and ACT3 through multiple insulating layers located between the second semiconductor layer SCL2 and the fifth conductive layer SDL1. For example, the second capacitor electrode CPE2 may be electrically connected to the second drain region D2 and the third source region S3 through a twelfth contact hole CH12, which is formed in the fifth insulating layer GI5 and the sixth insulating layer GI6 to expose portions of the second drain region D2 and the third source region S3. According to some embodiments, the second capacitor electrode CPE2 may function as the drain electrode of the second transistor T2 and the source electrode of the third transistor T3, and may be considered as part of the second and third transistors T2 and T3. For example, the second capacitor C2, the second transistor T2, and the third transistor T3 may share a single electrode commonly connected to the third node N3.

According to some embodiments, the fifth conductive layer SDL1 may further include at least one conductive pattern that forms another electrode of at least one circuit element included in the pixel PX or a connection pattern electrically connected to the at least one circuit element. For example, the fifth conductive layer SDL1 may further include the fifth and sixth conductive patterns CP5 and CP6 of the pixel PX.

The fifth conductive pattern CP5 may be electrically connected to the first conductive pattern CP1 through an insulating layer located between the fourth conductive layer GTL4 and the fifth conductive layer SDL1. For example, the fifth conductive pattern CP5 may be electrically connected to the first conductive pattern CP1 through a fifth contact hole CH5, which is formed in the sixth insulating layer GI6 to expose a portion of the first conductive pattern CP1. Additionally, the fifth conductive pattern CP5 may be electrically connected to another region of the third active layer ACT3 through multiple insulating layers located between the second semiconductor layer SCL2 and the fifth conductive layer SDL1. For example, the fifth conductive pattern CP5 may be electrically connected to the third drain region D3 through a sixth contact hole CH6, which is formed in the fifth insulating layer GI5 and the sixth insulating layer GI6 to expose a portion of the third drain region D3. According to some embodiments, the fifth conductive pattern CP5 may function as the drain electrode of the third transistor T3 and may be considered as part of the third transistor T3.

The sixth conductive pattern CP6 may be electrically connected to the third conductive pattern CP3 through an insulating layer located between the fourth conductive layer GTL4 and the fifth conductive layer SDL1. For example, the sixth conductive pattern CP6 may be electrically connected to the third conductive pattern CP3 through a seventh contact hole CH7, which is formed in the sixth insulating layer G16 to expose a portion of the third conductive pattern CP3. Additionally, the sixth conductive pattern CP6 may be electrically connected to another region of the second active layer ACT2 through multiple insulating layers located between the second semiconductor layer SCL2 and the fifth conductive layer SDL1. For example, the sixth conductive pattern CP6 may be electrically connected to the second source region S2 through an eighth contact hole CH8, which is formed in the fifth insulating layer GI5 and the sixth insulating layer G16 to expose a portion of the second source region S2. According to some embodiments, the sixth conductive pattern CP6 may function as the source electrode of the second transistor T2 and may be considered as part of the second transistor T2.

The seventh insulating layer ILD1 may be located on the sixth insulating layer G16 and the fifth conductive layer SDL1, and may cover the conductive patterns of the fifth conductive layer SDL1. For example, the seventh insulating layer ILD1 may cover the second capacitor electrode CPE2 and the fifth and sixth conductive patterns CP5 and CP6.

The sixth conductive layer SDL2 may be located on the seventh insulating layer ILD1. The sixth conductive layer SDL2 may include conductive patterns that contain a conductive material. For example, the sixth conductive layer SDL2 may include the data line DL connected to the pixel PX (or the second electrode of the second capacitor C2). The data line DL may form the second capacitor C2 together with the second capacitor electrode CPE2.

The eighth insulating layer ILD2 may be located on the seventh insulating layer ILD1 and the sixth conductive layer SDL2, and may cover the conductive patterns of the sixth conductive layer SDL2. For example, the eighth insulating layer ILD2 may cover the data line DL.

The seventh conductive layer SDL3 may be located on the eighth insulating layer ILD2. The seventh conductive layer SDL3 may include conductive patterns that contain a conductive material. For example, the seventh conductive layer SDL3 may include the first voltage line VDL and the initialization voltage line VIL. According to some embodiments, the seventh conductive layer SDL3 may further include the seventh conductive pattern CP7 of the pixel PX.

The first voltage line VDL may be electrically connected to the second conductive pattern CP2 through multiple insulating layers located between the fourth conductive layer GTL4 and the seventh conductive layer SDL3. For example, the first voltage line VDL may be electrically connected to the second conductive pattern CP2 through a ninth contact hole CH9, which is formed in the sixth insulating layer GI6, the seventh insulating layer ILD1, and the eighth insulating layer ILD2 to expose a portion of the second conductive pattern CP2. The first voltage line VDL may be electrically connected to the first source region S1 through the second conductive pattern CP2.

The initialization voltage line VIL may be electrically connected to the fourth conductive pattern CP4 through multiple insulating layers located between the fourth conductive layer GTL4 and the seventh conductive layer SDL3. For example, the initialization voltage line VIL may be electrically connected to the fourth conductive pattern CP4 through a tenth contact hole CH10, which is formed in the sixth insulating layer GI6, the seventh insulating layer ILD1, and the eighth insulating layer ILD2 to expose a portion of the fourth conductive pattern CP4. The initialization voltage line VIL may be electrically connected to the first capacitor electrode CPE1 through the fourth conductive pattern CP4.

The seventh conductive pattern CP7 may be electrically connected to the fifth conductive pattern CP5 through an insulating layer located between the fifth conductive layer SDL1 and the seventh conductive layer SDL3. For example, the seventh conductive pattern CP7 may be electrically connected to the fifth conductive pattern CP5 through an eleventh contact hole CH11, which is formed in the seventh insulating layer ILD1 and the eighth insulating layer ILD2 to expose a portion of the fifth conductive pattern CP5. The seventh conductive pattern CP7 may be electrically connected to the third drain region D3 and the first conductive pattern CP1 through the fifth conductive pattern CP5. Additionally, the seventh conductive pattern CP7 may be electrically connected to the first drain region D1 through the first conductive pattern CP1. According to some embodiments, the seventh conductive pattern CP7 may function as a connection pattern forming the second node N2.

According to some embodiments, the seventh conductive layer SDL3 may further include the second voltage line VSL of FIG. 2, but the present disclosure is not limited thereto. Alternatively, the second voltage line VSL may be located in another conductive layer included in the circuit layer CRL. The second voltage line VSL may be electrically connected to the second electrode CE of the light-emitting element ED either inside or around the display area DA.

The ninth insulating layer VIA may be located on the eighth insulating layer ILD2 and the seventh conductive layer SDL3, and may cover the conductive patterns of the seventh conductive layer SDL3. For example, the ninth insulating layer VIA may cover the first voltage line VDL, the initialization voltage line VIL, and the seventh conductive pattern CP7.

FIGS. 3 and 4 illustrate a structure in which the light-emitting element layer EDL is directly located on the ninth insulating layer VIA, but the present disclosure is not limited thereto. For example, the circuit layer CRL may further include an eighth conductive layer located on the ninth insulating layer VIA and including an eighth conductive pattern, and a tenth insulating layer covering the patterns of the eighth conductive layer. In this case, the light-emitting element layer EDL may be located on the tenth insulating layer. The eighth conductive pattern may be electrically connected to the seventh conductive pattern CP7 through a contact hole penetrating the tenth insulating layer. Additionally, the first electrode AE of the light-emitting element ED may be electrically connected to the eighth conductive pattern through a contact hole penetrating the tenth insulating layer. For example, the first electrode AE of the light- emitting element ED may be electrically connected to the seventh conductive pattern CP7 via the eighth conductive pattern. Furthermore, the numbers of conductive layers and insulating layers that may be included in the circuit layer CRL may vary.

The patterns included in each of the conductive layers of the circuit layer CRL, for example, the electrodes, the connection patterns (e.g., the first through seventh conductive patterns CP1 through CP7), and/or the wiring patterns may be single-layer or multi-layer patterns that contain at least one conductive material. For example, the conductive patterns included in each of the first conductive layer GTL1, the second conductive layer GTL2, the third conductive layer GTL3, the fourth conductive layer GTL4, the fifth conductive layer SDL1, the sixth conductive layer SDL2, and the seventh conductive layer SDL3 may contain at least one of molybdenum (Mo), aluminum (Al), chromium (Cr), gold (Au), silver (Ag), titanium (Ti), nickel (Ni), neodymium (Nd), copper (Cu), or other metals, their alloys, or other conductive materials, and may have a single-layer or multi-layer structure. At least two of the conductive layers of the circuit layer CRL may include the same material or different materials.

The insulating layers of the circuit layer CRL may include at least one insulating material and may have a single-layer or multi-layer structure. For example, the first, second, third, fourth, fifth, and sixth insulating layers GI1, GI2, GI3, GI4, GI5, and GI6, the seventh and eighth insulating layers ILD1 and ILD2, and the ninth insulating layer VIA may include an organic insulating material and/or an inorganic insulating material and may have a single-layer or multi-layer structure. At least two of the insulating layers of the circuit layer CRL may include the same material or different materials.

According to some embodiments, the first, second, third, fourth, fifth, and sixth insulating layers GI1, GI2, GI3, GI4, GI5, and G16 and the seventh and eighth insulating layers ILD1 and ILD2 may be single-layer or multi-layer inorganic insulating layers that include an inorganic insulating material (e.g., silicon nitride, silicon oxide, silicon oxynitride, titanium oxide, aluminum oxide, or other inorganic insulating materials). Therefore, the circuit elements located in the circuit layer CRL can be adequately protected, ensuring reliability while reducing or minimizing the thickness of the circuit layer CRL.

According to some embodiments, the ninth insulating layer VIA may include an organic insulating material (e.g., an acrylic resin, an epoxy resin, a phenolic resin, a polyamide resin, a polyimide resin, or other organic insulating materials). The upper surface of the ninth insulating layer VIA may be substantially flat. Thus, the upper surface of the ninth insulating layer VIA may be substantially flat. However, embodiments according to the present disclosure are not limited to this. For example, the ninth insulating layer VIA may be formed using an inorganic insulating material and then flattened through a planarization process. The material and/or structure of each insulating layer of the circuit layer CRL may vary according to some embodiments.

According to some embodiments, the number and/or size of the contact holes formed in the circuit layer CRL may be reduced or minimized. For example, in a high-resolution display device with smaller pixels PX, the number and/or size of the contact holes may be reduced to optimize the design of the circuit layer CRL. For example, at least some of the first through twelfth contact holes CH1 through CH12, which are located in each pixel region, may have reduced or minimized widths and areas, thereby achieving a relatively large aspect ratio (e.g., the ratio of the maximum depth in the third direction DR3 to the maximum width in the first direction DR1 or second direction DR2) for the contact holes. When the aspect ratio of the contact holes increases, the contact holes may not be able to be properly filled with a conductive material, leading to reduced contact quality or the occurrence of disconnections.

For example, in the case of contact holes that penetrate numerous insulating layers, such as the first contact hole CH1 or the second contact hole CH2, reducing the width or area of the contact holes may significantly increase their aspect ratio. For example, if the width or area of deep contact holes such as the first contact hole CH1 or the second contact hole CH2 is reduced and the contact holes have a large aspect ratio of 0.6 or greater, or even 1 or greater, the contact holes may not be able to be properly filled with a conductive material, increasing the probability of contact defects.

In order to prevent or reduce this, according to some embodiments, at least one conductive pattern of the circuit layer CRL, which is connected to a pattern located below a contact hole, may be formed using inorganic ink containing conductive particles. Accordingly, the at least one conductive pattern may include conductive particles. For example, the at least one conductive pattern may be formed using metal ink and may include metal particles (e.g., Ti metal particles, Al metal particles, or other metal particles).

According to some embodiments, at least one conductive pattern that fills a high aspect ratio contact hole (e.g., a contact hole with an aspect ratio of 0.3 or greater) among the contact holes in the circuit layer CRL may be formed using inorganic ink containing conductive particles (e.g., metal ink). Accordingly, the at least one conductive pattern that fills the high aspect ratio contact hole may include conductive particles (e.g., metal particles).

For example, the first and second conductive patterns CP1 and CP2 of the fourth conductive layer GTL4, which fill the first and second contact holes CH1 and CH2 that continuously penetrate the first, second, third, fourth, and fifth insulating layers GI1, GI2, GI3, GI4, and GI5, may be formed using inorganic ink containing conductive particles (e.g., metal ink). Accordingly, the first and second conductive patterns CP1 and CP2 may include conductive particles (e.g., metal particles).

According to some embodiments, conductive patterns in the same layer that are connected to their respective lower patterns through their respective contact holes may be formed simultaneously (or concurrently) using the same material. For example, the first, second, third, and fourth conductive patterns CP1, CP2, CP3, and CP4 of the fourth conductive layer GTL4 may be simultaneously (or concurrently) formed using inorganic ink containing conductive particles. Accordingly, the third and fourth conductive patterns CP3 and CP4 may also include conductive particles. By filling contact holes penetrated by conductive patterns located in the same conductive layer simultaneously (or concurrently), the process of forming the circuit layer CRL can be simplified, and the manufacturing efficiency of the display device 10 can be relatively improved.

According to some embodiments, some conductive patterns among the conductive patterns of a conductive layer that includes at least one conductive pattern formed using inorganic ink containing conductive particles may be formed using different materials in different processes. Accordingly, some conductive patterns may include different materials from other conductive patterns even if they all are located within the same conductive layer.

For example, among the conductive patterns of the fourth conductive layer GTL4 illustrated in FIG. 3, the first, second, third, and fourth conductive patterns CP1, CP2, CP3, and CP4 may be formed using inorganic ink containing conductive particles and may thus include conductive particles. On the other hand, at least one of the second gate electrode GE2, the third gate electrode GE3, or the wiring of the fourth conductive layer GTL4 may be formed from a conductive film formed by depositing a conductive material such as metal, and may thus include a metal layer (or a uniform conductive layer containing other conductive materials in addition to metal). According to some embodiments, the fourth conductive layer GTL4 may further include wiring formed using inorganic ink or wiring formed by etching a conductive material deposited such as metal. For example, the wiring of the conductive layer GTL4 may be formed using inorganic ink containing conductive particles along with the first, second, third, and fourth conductive patterns CP1, CP2, CP3, and CP4, or may be formed from a conductive film deposited with metal, like the second and third gate electrodes GE2 and GE3. Accordingly, the wiring of the fourth conductive layer GTL4 may include conductive particles or a metal layer (or a uniform conductive layer containing other conductive materials in addition to metal). When some conductive patterns within the same conductive layer (e.g., the fourth conductive layer GTL4) are formed using a different material from other conductive patterns, the material and/or structure of the conductive patterns can be differentiated or optimized to meet the physical and/or electrical properties required for each conductive pattern. As a result, the operational characteristics of pixels PX can be relatively improved or optimized, and the reliability of the display device 10 can be ensured.

According to some embodiments, the conductive patterns of the fourth conductive layer GTL4 illustrated in FIG. 4 may be formed simultaneously (or concurrently) using the same material, and may thus include the same material. For example, the first, second, third, and fourth conductive patterns CP1, CP2, CP3, and CP4 and the second and third gate electrodes GE2 and GE3 of the fourth conductive layer GTL4 may be formed simultaneously (or concurrently) using inorganic ink containing conductive particles, and may thus include conductive particles. According to some embodiments, the fourth conductive layer GTL4 may further include at least one wiring formed using inorganic ink containing conductive particles along with the conductive patterns of the fourth conductive layer GTL4 illustrated in FIG. 4, and the wiring of the fourth conductive layer GTL4 may include conductive particles. By forming the conductive patterns of the fourth conductive layer GTL4 simultaneously (or concurrently) using the same material, the manufacturing process of the display device 10 can be simplified, and the manufacturing efficiency of the display device 10 can be relatively improved.

However, the embodiments are not limited to this. For example, the material and processing method for forming each conductive pattern may be determined in consideration of at least one of the size or shape of each conductive pattern, the electrical characteristics of each conductive pattern, the size or shape of each contact hole (e.g., the width, depth, and/or aspect ratio of each contact hole), the quality of contact through each contact hole, and the processing efficiency.

In the aforementioned embodiments, the conductive patterns of the fourth conductive layer GTL4 have been illustrated as conductive patterns that can be formed using inorganic ink containing conductive particles, but the present disclosure is not limited thereto. For example, among the conductive patterns located in other conductive layers of the circuit layer CRL, one or more conductive patterns connected to underlying semiconductor patterns or conductive patterns through one or more contact holes may be formed using inorganic ink containing conductive particles, ensuring that the conductive patterns are stably formed to fill the contact holes therebelow. For example, the conductive patterns may completely fill the underlying contact holes.

The light-emitting element layer EDL may be located on the circuit layer CRL and may be located in the display area DA. For example, the light-emitting element layer EDL may be located on the circuit layer CRL in the display area DA.

The light-emitting element layer EDL may include a pixel defining layer PDL that defines an emission area EA of the pixel PX and a light-emitting element ED that is located in the emission area EA of the pixel PX. According to some embodiments, the light-emitting element layer EDL may further include a spacer located on a portion of the pixel defining layer PDL.

The light-emitting element ED may include a first electrode AE (e.g., an anode), a second electrode CE (e.g., a cathode), and an emission layer EL located between the first electrode AE and the second electrode CE. According to some embodiments, the first electrode AE, the emission layer EL, and the second electrode CE may be sequentially stacked on the circuit layer CRL along the third direction DR3.

According to some embodiments, the light-emitting element ED may further include at least one intermediate layer. For example, the light-emitting element ED may further include a first intermediate layer (e.g., a hole transport layer including a hole injection layer) located between the first electrode AE and the emission layer EL, and a second intermediate layer (e.g., an electron transport layer including an electron injection layer) located between the emission layer EL and the second electrode CE. According to some embodiments, at least one intermediate layer may be a common film formed across the entire display area DA.

FIGS. 3 and 4 illustrates embodiments where the light-emitting element ED includes a single emission layer EL, but the present disclosure is not limited thereto. For example, the light-emitting element ED may be formed with a tandem structure comprising at least two emission layers (e.g., the emission layer EL of FIGS. 3 and 4 and an additional emission layer overlapping with the emission layer EL) stacked in the third direction DR3. Additionally, the light-emitting element ED may further include a charge generation layer located between the at least two emission layers. The emission layer EL may be formed as a common film across the entire display area DA, or may be located in each pixel region in a shape and/or size corresponding to the emission area EA of each pixel PX.

According to some embodiments, the display device 10 may further include an optical layer located on the light-emitting element layer EDL. The optical layer may include a color filter layer (e.g., a color filter layer containing color filters corresponding to the emission colors of pixels PX) and/or a light conversion layer (e.g., a light conversion layer containing wavelength conversion patterns that convert the color or wavelength of light emitted from the light-emitting elements ED of at least some pixels PX). Accordingly, the color or wavelength of the light emitted from the pixel PX may be appropriately controlled. The optical layer may be selectively located on the display device 10 as needed. For example, depending on the type or structure of the light- emitting element ED or the structure of the light-emitting element layer EDL, the display device 10 may selectively include at least one optical layer.

The first electrode AE of the light-emitting element ED may be located on the circuit layer CRL. For example, the first electrode AE may be located on the ninth insulating layer VIA corresponding to the emission area EA.

The light-emitting element ED may be electrically connected to the first transistor T1. For example, the first electrode AE of the light-emitting element ED may be electrically connected to the seventh conductive pattern CP7 through a via hole VH, which is formed in the ninth insulating layer VIA, and may be electrically connected to the first drain region D1 of the first transistor T1 through the seventh conductive pattern CP7, the fifth conductive pattern CP5, and the first conductive pattern CP1. The first electrode AE may include at least one conductive material and may have a single-layer or multi-layer structure. According to some embodiments, the first electrode AE may include a reflective electrode layer containing a high-reflectivity metal material.

FIGS. 3 and 4 illustrate embodiments where the first electrode AE of the light-emitting element ED is directly located on the circuit layer CRL, but the present disclosure is not limited thereto. For example, the emission layer EL may be formed across the entire display area DA, and an additional electrode or pattern may be located below the first electrode AE of the light-emitting element ED to adjust or optimize the resonance distance of the light generated by the light-emitting element ED, corresponding to the emission wavelength of the pixel PX. The additional electrode or pattern may be located between the circuit layer CRL and the light- emitting element layer EDL or within the circuit layer CRL or light-emitting element layer EDL (e.g., in the upper portion of the circuit layer CRL or the lower portion of the light-emitting element layer EDL).

The emission layer EL of the light-emitting element ED may include a polymer material or a low-molecular-weight material. The light emitted from the emission layer EL may contribute to the display of an image. According to some embodiments, the emission layer EL may be provided for the pixel PX, and the emission layer EL of the pixel PX may emit visible light of a color or wavelength corresponding to the pixel PX. According to some embodiments, the emission layer EL may be a common layer shared by multiple pixels PX of different colors, and at least some of the emission areas EA of the multiple pixels PX may be provided with a light conversion layer and/or color filters corresponding to the color (or wavelength) of light to be emitted from the respective multiple pixels PX.

The second electrode CE of the light-emitting element ED may include a conductive material. According to some embodiments, the second electrode CE may be a common layer formed across the entire display area DA in a shape that covers the emission layer EL and the pixel defining layer PDL. According to some embodiments, the second electrode CE may include a transparent conductive oxide (TCO) such as indium tin oxide (ITO) or indium zinc oxide (IZO), or a semi- transmissive conductive material such as magnesium (Mg), silver (Ag), or an alloy of Mg and Ag.

The pixel defining layer PDL may have an opening corresponding to each emission area EA and may surround each emission area EA. For example, the pixel defining layer PDL may be formed to cover the edges of the first electrode AE of the light-emitting element ED and may include an opening that exposes the rest of the first electrode AE. The overlapping area of the exposed portion of the first electrode AE and the emission layer EL (or a region including this overlapping area) may be defined as the emission area EA of the pixel PX.

According to some embodiments, the pixel defining layer PDL may include an organic insulating material. For example, the pixel defining layer PDL may include a polyacrylate resin, an epoxy resin, a phenolic resin, a polyamide resin, a polyimide resin, an unsaturated polyester resin, a polyphenylenether resin, a polyphenylene sulfide resin, or benzocyclobutene (BCB), or other organic insulating materials.

The encapsulation layer TFEL may be located on the light-emitting element layer EDL. The encapsulation layer TFEL may cover the light-emitting element layer EDL in the display area DA and may extend into the non-display area NDA to contact the circuit layer CRL. For example, the encapsulation layer TFEL may be located in the display area DA to cover the light-emitting element layer EDL, and the end of the encapsulation layer TFEL may be located in part of the non-display area NDA adjacent to the display area DA. The encapsulation layer TFEL may block the infiltration of oxygen or moisture into the light-emitting element layer EDL and may mitigate electrical and/or physical impacts on the circuit layer CRL and the light-emitting element layer EDL.

According to some embodiments, the encapsulation layer TFEL may be a multi-layer structure including inorganic and organic encapsulation layers. For example, the encapsulation layer TFEL may include a first inorganic encapsulation layer TFE1, an organic encapsulation layer TFE2, and a second inorganic encapsulation layer TFE3 that are sequentially arranged on the light-emitting element layer EDL. The encapsulation layer TFEL may also be replaced with other types, structures, and/or materials of encapsulation members. For example, the light-emitting element layer EDL may be encapsulated using an upper substrate including an insulating material such as glass, or a protective layer including a single or multi-layer capping layer.

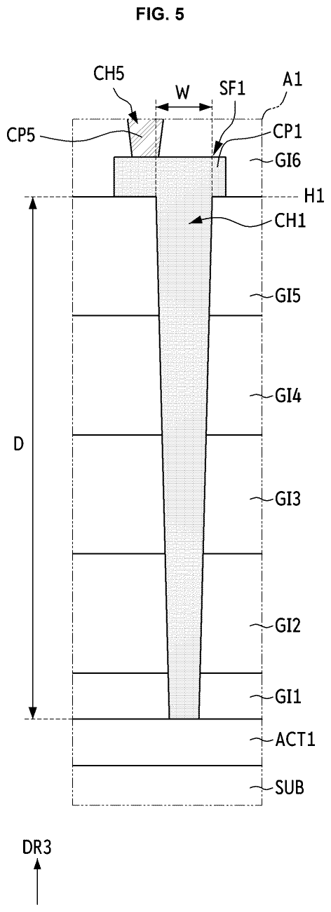

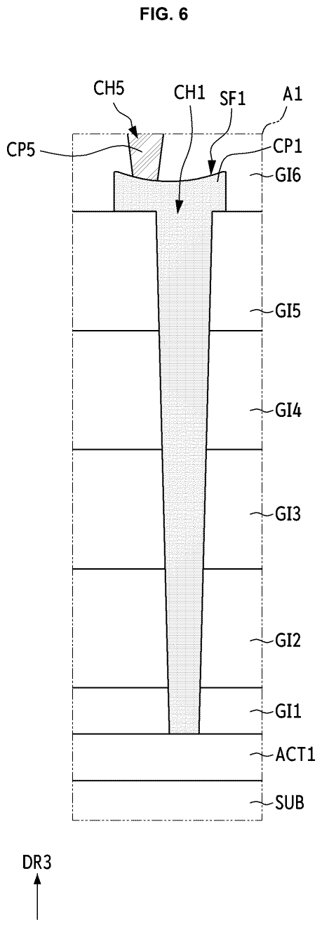

FIG. 5 is a cross-sectional view illustrating a conductive pattern according to some embodiments. FIG. 6 is a cross-sectional view illustrating a conductive pattern according to some embodiments. For example, FIGS. 5 and 6 provide detailed illustrations of the first conductive pattern CP1 located in part A1 of FIG. 3 and illustrate different embodiments of the shape of an upper surface SF1 of the first conductive pattern CP1.

Referring to FIGS. 3 through 6, the first conductive pattern CP1 may be located within and around the first contact hole CH1. For example, a portion of the first conductive pattern CP1 located at a height less than or equal to a first height H1, which corresponds to the maximum height of the first contact hole CH1, may be located within the first contact hole CH1, and another portion of the first conductive pattern CP1 located at a greater height than the first height H1 may be located above the first contact hole CH1 and may extend around the first contact hole CH1. For example, the first conductive pattern CP1 may cover the first contact hole CH1 and may be arranged around the perimeter of the first contact hole CH1, on a plane (e.g., a plane intersecting the third direction DR3).

According to some embodiments, the first contact hole CH1 may penetrate at least two insulating layers of the circuit layer CRL and may have a depth D that is greater than or equal to the thickness of the at least two insulating layers. According to some embodiments, to appropriately position the first conductive pattern CP1 inside the pixel region where the pixel PX is located and to ensure the electrical stability of the first conductive pattern CP1, the size of the first contact hole CH1 may be limited. For example, a width W or the area of the first contact hole CH1 may be limited to ensure the electrical stability of the circuit elements located in the circuit layer CRL. As the width W or the area of the first contact hole CH1 decreases, the aspect ratio (e.g., the depth D-to-width W ratio in FIG. 5) of the first contact hole CH1 may increase. For example, the aspect ratio of the first contact hole CH1 may be 0.3 or greater. If the width W of the first contact hole CH1 is reduced relative to the depth D, the area occupied by the first contact hole CH1 on a plane may decrease. Accordingly, the distance between adjacent patterns can be appropriately secured, thereby preventing or reducing short defects, and efficiently utilizing the limited pixel area.

According to some embodiments, the display device 10 may be a high- resolution display device with a high degree of integration in the circuit layer CRL, and the region where the first contact hole CH1 is formed may be further reduced or minimized. Accordingly, the aspect ratio of the first contact hole CH1 may further increase. According to some embodiments, to appropriately position the circuit elements of the pixel circuit within a narrow pixel region, the circuit layer CRL may include more semiconductor layers and/or conductive layers. Additionally, the number of insulating layers included in the circuit layer CRL may also increase. Accordingly, the depth D of at least one contact hole, including the first contact hole CH1, may increase.

When the first contact hole CH1 has a limited width or area and penetrates multiple insulating layers, the aspect ratio of the first contact hole CH1 may increase as its depth D increases. For example, the first contact hole CH1 may be formed to sequentially penetrate the first, second, third, fourth, and fifth insulating layers GI1, GI2, GI3, GI4, and GI5, and the aspect ratio of the first contact hole CH1 may be 0.6 or greater, or 1 or greater. For example, to optimize the design of the circuit layer CRL, the first contact hole CH1 may be formed with a depth D greater than its width W, and the aspect ratio of the first contact hole CH1 may be 1 or greater.

When the depth D of the first contact hole CH1 increases, there is a higher likelihood that the first conductive pattern CP1 may not be properly filled inside the first contact hole CH1 during its formation process. For example, if the depth D of the first contact hole CH1 increases, when a conductive film is deposited to form the first conductive pattern CP1, the conductive film may excessively accumulate at the entrance of the first contact hole CH1, protruding in an overhang shape and potentially blocking the entrance of the first contact hole CH1. Consequently, the conductive film may not be properly deposited inside the lower portion of the first contact hole CH1 (e.g., including the bottom surface of the first contact hole CH1). This may result in contact defects between the first conductive pattern CP1 and the first active layer ACT1.

To prevent or reduce this, according to some embodiments, the first conductive pattern CP1 may be formed using inorganic ink containing conductive particles. Additionally, according to some embodiments, the region around a first pattern area where the first conductive pattern CP1 is to be formed is covered with a hydrophobic mask pattern, and the inorganic ink is applied to the first pattern area, allowing the first contact hole CH1 to be stably filled with the inorganic ink. For example, the inorganic ink may completely fill the first contact hole CH1 without voids. The inorganic ink is then solidified and processed (or transformed) into the first conductive pattern CP1. Accordingly, the first conductive pattern CP1 that fills the first contact hole CH1 may be formed. A detailed description of a method for forming the first conductive pattern CP1 according to some embodiments will be provided later.

The first conductive pattern CP1 formed from the inorganic ink may include conductive particles contained in the inorganic ink. For example, the first conductive pattern CP1 may include metal particles from metal ink used as the inorganic ink. Additionally, the first conductive pattern CP1 may stably fill the first contact hole CH1. For example, the first conductive pattern CP1 may completely fill the first contact hole CH1. As a result, the first conductive pattern CP1 can be stably connected to the first active layer ACT1.

The upper surface SF1 of the first conductive pattern CP1 may be substantially flat. Here, the expression “substantially flat” may mean that the upper surface SF1 of the first conductive pattern CP1 has a curvature within a predetermined tolerance. For example, the upper surface SF1 of the first conductive pattern CP1 may be either completely flat without any curvature or relatively flat with a gentle step height below a predetermined threshold. According to some embodiments, the threshold for curvature may be determined by whether another contact hole can be directly formed on the upper surface SF1 of the first conductive pattern CP1.

For example, the upper surface SF1 of the first conductive pattern CP1 may be formed as a substantially or completely flat plane, as illustrated in FIG. 5, or may be formed as a relatively gentle curved surface (e.g., concave) with a gradual step height, as illustrated in FIG. 6. The shape and density of the first conductive pattern CP1 may vary depending on the type or characteristics of the inorganic ink used for forming the first conductive pattern CP1 and the process conditions applied during the formation process.

According to some embodiments, during the process of transforming the inorganic ink filled in the first contact hole CH1 into the first conductive pattern CP1, a coffee-ring effect may occur. As a result, the first conductive pattern CP1 may have a shape in which the height is greater at the edges than at the center. For example, as the solvent in the inorganic ink applied inside and around the first contact hole CH1 evaporates, some of the conductive particles (e.g., metal particles) contained in the inorganic ink may concentrate at the edges of the inorganic ink's surface. Consequently, the upper surface SF1 of the first conductive pattern CP1 may have a shape where the height gradually increases from the center toward the edges, as illustrated in FIG. 6.

According to some embodiments, at least one insulating layer, a contact hole penetrating the at least one insulating layer, and another conductive pattern that fills the contact hole and is electrically connected to the first conductive pattern CP1 through the contact hole may be located on the first conductive pattern CP1. For example, the sixth insulating layer GI6, a fifth contact hole CH5 penetrating the sixth insulating layer GI6, and a fifth conductive pattern CP5 electrically connected to the first conductive pattern CP1 through the fifth contact hole CH5 may be located on the first conductive pattern CP1.

The fifth contact hole CH5 may be formed to expose a portion of the first conductive pattern CP1. The first and fifth contact holes CH1 and CH5 may or may not overlap with each other in the thickness direction (e.g., a third direction DR3) of the substrate SUB.

According to some embodiments, the first and fifth contact holes CH1 and CH5 may not completely overlap in the third direction DR3. For example, a portion of the fifth contact hole CH5 may overlap with the first contact hole CH1 in the third direction DR3, while another portion of the fifth contact hole CH5 may not overlap with the first contact hole CH1 in the third direction DR3. Alternatively, the fifth contact hole CH5 may not overlap with the first contact hole CH1 in the third direction DR3. For example, when viewed from above, the first and fifth contact holes CH1 and CH5 may be spaced apart from each other. By arranging the first and fifth contact holes CH1 and CH5 to be at least partially offset, process margins can be secured, and the stability or ease of the process can be relatively improved.

The fifth conductive pattern CP5 may partially or entirely fill the fifth contact hole CH5. The fifth conductive pattern CP5 may be in contact with the first conductive pattern CP1 inside the fifth contact hole CH5. The fifth conductive pattern CP5 is formed after the formation of the first conductive pattern CP1, and the first and fifth conductive patterns CP1 and CP5 may be formed in different process steps. The first and fifth conductive patterns CP1 and CP5 may include the same material or different materials.

According to some embodiments, the fifth conductive pattern CP5 may be formed using inorganic ink containing conductive particles (e.g., metal particles). Accordingly, the fifth conductive pattern CP5 may include conductive particles. According to some embodiments, the fifth conductive pattern CP5 may completely fill the fifth contact hole CH5. As a result, the contact quality between the first and fifth conductive patterns CP1 and CP5 can be ensured or relatively improved.

According to some embodiments, the fifth conductive pattern CP5 may be formed by depositing a conductive material such as metal to form a conductive film and then etching the conductive film. Accordingly, the fifth conductive pattern CP5 may include a metal layer (or a uniform conductive layer containing other conductive materials in addition to metal). According to some embodiments, the aspect ratio of the fifth contact hole CH5 may be smaller than the aspect ratio of the first contact hole CH1. Thus, a conductive film with an appropriate thickness and/or shape can be stably formed inside the fifth contact hole CH5. As a result, the contact quality between the first and fifth conductive patterns CP1 and CP5 can be ensured.

In this disclosure, an insulating layer located on a conductive pattern that fills a predetermined contact hole may be referred to as an “upper insulating layer,” another contact hole located on the conductive pattern and penetrating the upper insulating layer may be referred to as an “upper contact hole,” and another pattern electrically connected to the conductive pattern through the upper contact hole (e.g., a semiconductor pattern or a conductive pattern connected to the conductive pattern from above) may be referred to as an “upper pattern.” For example, the sixth insulating layer GI6, which is located on the first conductive pattern CP1, the fifth contact hole CH5, and the fifth conductive pattern CP5 may be referred to as an upper insulating layer, an upper contact hole, and an upper pattern (or upper conductive pattern), respectively, for the first conductive pattern CP1 that fills the first contact hole CH1.

Furthermore, in this disclosure, an insulating layer located below a conductive pattern that fills a predetermined contact hole may be referred to as a “lower insulating layer,” a contact hole located below the conductive pattern and penetrating the lower insulating layer may be referred to as a “lower contact hole,” and another pattern electrically connected to the conductive pattern through the lower contact hole (e.g., a semiconductor pattern or a conductive pattern electrically connected to the conductive pattern from below) may be referred to as a “lower pattern.” For example, each of the first, second, third, fourth, and fifth insulating layers GI1, GI2, GI3, GI4, and GI5, which are located below the first conductive pattern CP1, the first contact hole CH1, and the first active layer ACT1 may be referred to as a lower insulating layer, a lower contact hole, and a lower pattern, respectively, for the first conductive pattern CP1 that fills the first contact hole CH1.

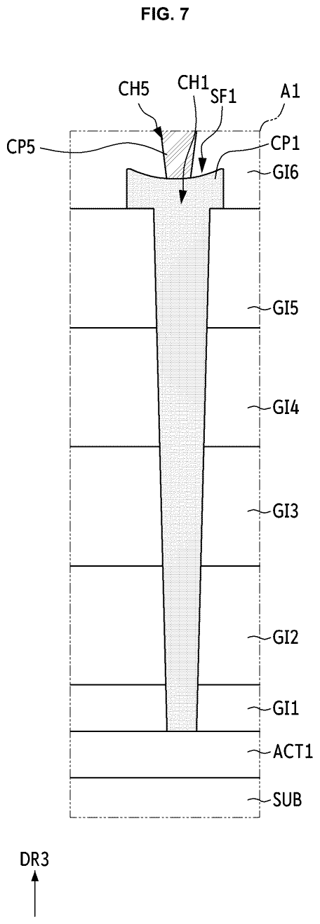

FIG. 7 is a cross-sectional view illustrating a conductive pattern according to some embodiments. For example, FIG. 7 provides a detailed view of the first conductive pattern CP1 arranged in part A1 of FIG. 4. FIG. 7 illustrates different embodiments from FIG. 6 in terms of the arrangement structure of first and fifth contact holes CH1 and CH5. In this disclosure, components that are substantially identical or similar to those described earlier are assigned the same reference numerals, and redundant descriptions thereof will be omitted.

Referring to FIG. 7, the first and fifth contact holes CH1 and CH5 may overlap with each other in the thickness direction of the substrate SUB (e.g., the third direction DR3). For example, the central axes of the first and fifth contact holes CH1 and CH5 may either coincide or be positioned adjacent to each other. Additionally, the fifth contact hole CH5 and the fifth conductive pattern CP5 may be directly located on the central portion of the first conductive pattern CP1.

FIG. 7 illustrates modified embodiments of the embodiments of FIG. 6, but the embodiments of FIG. 7 may also be combined with the embodiments of FIG. 5. For example, the fifth contact hole CH5 of FIG. 7 may be arranged to fully overlap the first contact hole CH1 of FIG. 5 and be positioned on the first conductive pattern CP1 of FIG. 5. Additionally, the features of each of the embodiments disclosed in this disclosure may be applied individually or in combination with the features of other embodiments.

According to some embodiments, the upper surface SF1 of the first conductive pattern CP1 may be substantially flat or have a gentle step height. For example, the central portion of the first conductive pattern CP1, which covers the first contact hole CH1, may be completely flat or have a low step height suitable for directly forming the fifth contact hole CH5 and the fifth conductive pattern CP5. Accordingly, the fifth contact hole CH5 and the fifth conductive pattern CP5 can be stably formed on the central portion of the first conductive pattern CP1.

According to the above-described embodiments, by arranging upper and lower contact holes to overlap, the design structure of the circuit layer CRL can be optimized. For example, when the fifth contact hole CH5 and the fifth conductive pattern CP5 are directly located on the central portion of the first conductive pattern CP1, it is no longer necessary to form the first conductive pattern CP1 broadly, allowing the width (or area) of the first conductive pattern CP1 to be reduced or minimized. As a result, the electrical stability between the first conductive pattern CP1 and other neighboring conductive patterns can be ensured or relatively improved. Additionally, by reducing or minimizing the area occupied by the first conductive pattern CP1 in each pixel region, the design structure of the circuit layer CRL can be optimized.

According to the embodiments of FIGS. 5 through 7, by stably filling the first contact hole CH1 with the first conductive pattern CP1, the contact quality through the first contact hole CH1 can be relatively improved. As a result, even when the display device 10 includes a contact hole with a large depth D and a high aspect ratio, such as the first contact hole CH1, contact defects in the display device 10 can be prevented or reduced, and electrical signals can be transmitted relatively stably.

Furthermore, according to these embodiments, the first conductive pattern CP1 may be formed using inorganic ink containing a material capable of withstanding high-temperature processes (e.g., heat-resistant inorganic ink that can endure the process temperatures for forming the first conductive pattern CP1 and the temperatures of subsequent processes conducted thereafter). Accordingly, defects in the display device 10 can be prevented or reduced, and reliability can be ensured.

FIGS. 5 through 7 illustrate the first conductive pattern CP1 as a conductive pattern that can be formed according to some embodiments, but embodiments according to the present disclosure are not limited thereto. Alternatively, for example, one or more conductive patterns that fill one or more contact holes (e.g., multiple conductive patterns including the first conductive pattern CP1 or multiple conductive patterns excluding the first conductive pattern CP1) in the circuit layer CRL may be formed using inorganic ink containing conductive particles. Accordingly, the conductive patterns can stably (e.g., completely) fill the contact holes and may have a substantially flat upper surface.

Moreover, FIGS. 5 through 7 illustrate the first conductive pattern CP1 as penetrating multiple insulating layers at once, but the present disclosure is not limited thereto. Alternatively, for example, a high aspect ratio contact hole may be divided into multiple sub-contact holes, and sub-conductive patterns filling the respective sub- contact holes may be stacked in a dual or triple structure to connect upper and lower patterns. In this case, inorganic ink may be used to form at least one of the sub- conductive patterns with a substantially flat upper surface. As a result, the contact holes penetrated by the sub-conductive patterns can be aligned, and the area occupied by the high aspect ratio contact hole can be reduced or minimized. For example, when forming a high aspect ratio contact hole with an aspect ratio of 1 or greater, the high aspect ratio contact hole may be divided into an upper contact hole and a lower contact hole overlapping in the third direction DR3, and a lower conductive pattern filling the lower contact hole may be formed using inorganic ink. Consequently, the upper contact hole and the upper conductive pattern filling the upper contact hole can be directly located on the lower conductive pattern.

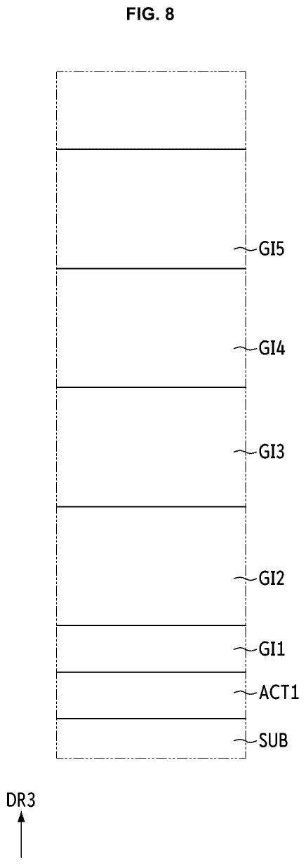

FIGS. 8 through 15 are cross-sectional views illustrating a method for manufacturing a display device according to some embodiments. For example, FIGS. 8 through 15 sequentially illustrate manufacturing processes for forming the first conductive pattern CP1 according to the embodiments of FIG. 5 during the fabrication of the display device 10 described in the embodiments of FIG. 3 or 4. The first conductive pattern CP1 according to the embodiments of FIG. 6 or 7 may also be formed in substantially the same manner as the first conductive pattern CP1 according to the embodiments of FIG. 5. FIGS. 8 through 15 illustrate a portion of the display device 10 being manufactured, corresponding to part A1 of FIG. 4.

Referring to FIGS. 3 through 8, on the substrate SUB (or on a buffer layer thereon), patterns of at least one semiconductor layer and/or conductive layer, including a lower pattern that is located below the first conductive pattern CP1 and is electrically connected to the first conductive pattern CP1 through the first contact hole CH1, may be formed, and insulating layers covering the patterns of the at least one semiconductor layer and/or conductive layer may also be formed. For example, the first semiconductor layer SCL1, including the first active layer ACT1, may be formed on the substrate SUB, and the first, second, third, fourth, and fifth insulating layers GI1, GI2, GI3, GI4, and GI5 may be sequentially formed on the first semiconductor layer SCL1.

The first semiconductor layer SCL1 may be formed through a semiconductor film formation process (e.g., a deposition process) using at least one semiconductor material (e.g., a semiconductor material previously described as the material of the first active layer ACT1) and a semiconductor film patterning process (e.g., an etching process using a mask). Each of the first, second, third, fourth, and fifth insulating layers GI1, GI2, GI3, GI4, and GI5 may be formed through the formation of at least one insulating film (e.g., a deposition process) using at least one insulating material (e.g., an inorganic insulating material previously described).

According to some embodiments, as illustrated in FIGS. 3 and 4, when the first conductive layer GTL1, the second conductive layer GTL2, the third conductive layer GTL3, and the second semiconductor layer SCL2 are located between the first and fifth insulating layers GI1 and GI5, after forming the first insulating layer GI1 on the first semiconductor layer SCL1, the first conductive layer GTL1, the second insulating layer GI2, the second conductive layer GTL2, the third insulating layer GI3, the third conductive layer GTL3, the fourth insulating layer GI4, the second semiconductor layer SCL2, and the fifth insulating layer GI5 may be sequentially formed on the first insulating layer GI1. According to some embodiments, each of the first, second, and third conductive layers GTL1, GTL2, and GTL3 may be formed through a conductive film formation process (e.g., a deposition process) using at least one conductive material (e.g., a conductive material previously described) and a conductive film patterning process (e.g., an etching process using a mask). The second semiconductor layer SCL2 may be formed through the semiconductor film formation process using at least one semiconductor material (e.g., a semiconductor material previously described as the material of the second active layer ACT2) and a semiconductor film patterning process.

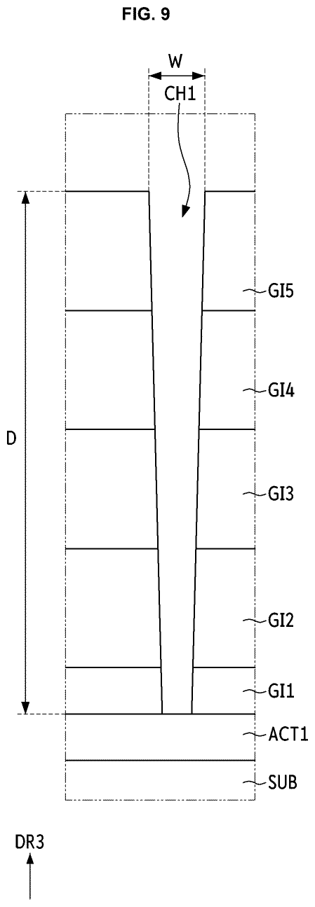

Referring to FIG. 9, a contact hole exposing a portion of its lower pattern may be formed to penetrate the underlying insulating layers. For example, the first contact hole CH1 may be formed by etching the first, second, third, fourth, and fifth insulating layers GI1, GI2, GI3, GI4, and GI5, which are located on the first active layer ACT1 in the region where the first conductive pattern CP1 is to be formed. The first contact hole CH1 may penetrate the first, second, third, fourth, and fifth insulating layers GI1, GI2, GI3, GI4, and GI5 to expose a portion of the first active layer ACT1. In the step of forming the first contact hole CH1, the second, third, and fourth contact holes CH2, CH3, and CH4 of FIG. 3 may also be formed. The second contact hole CH2 may be formed to penetrate the first, second, third, fourth, and fifth insulating layers GI1, GI2, GI3, GI4, and GI5 to expose another portion of the first active layer ACT1. The third contact hole CH3 may be formed to penetrate the second, third, fourth, and fifth insulating layers GI2, GI3, GI4, and GI5 to expose a portion of the first gate electrode GE1. The fourth contact hole CH4 may be formed to penetrate the third, fourth, and fifth insulating layers GI3, GI4, and GI5 to expose a portion of the first capacitor electrode CPE1.

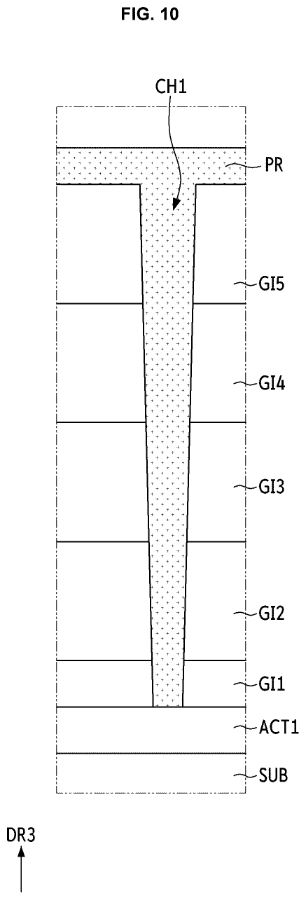

Referring to FIGS. 10 through 12, a mask pattern PRM covering the region around the first pattern area PA1, where the first conductive pattern CP1 is to be formed, may be formed on the lower insulating layers and the first contact hole CH1. The mask pattern PRM may expose the first pattern area PA1.

According to some embodiments, the mask pattern PRM may be a photoresist mask formed by a photolithography process using hydrophobic photoresist PR. For example, as illustrated in FIG. 10, the hydrophobic photoresist PR may be applied over the lower insulating layers and the first contact hole CH1 on the first active layer ACT1. For example, the hydrophobic photoresist PR may be coated over the first, second, third, fourth, and fifth insulating layers GI1, GI2, GI3, GI4, and GI5, where the first contact hole CH1 is formed.

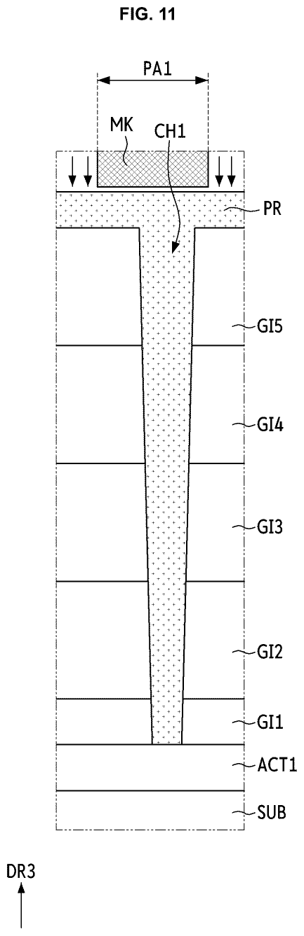

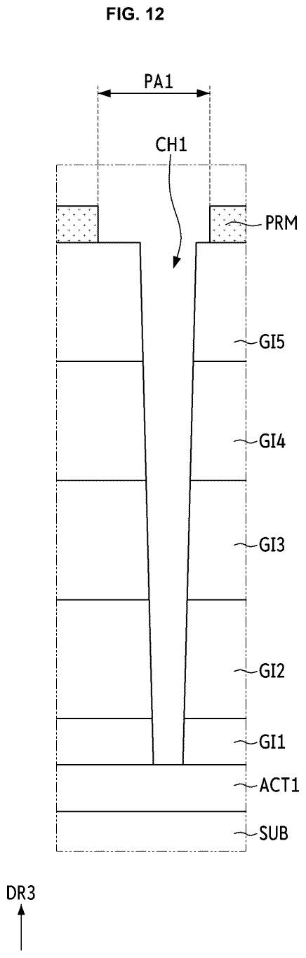

Thereafter, the hydrophobic photoresist PR may be processed into the mask pattern PRM. For example, as illustrated in FIG. 11, a mask MK may be located on a portion of the hydrophobic photoresist PR located in the first pattern area PA1, another portion of the hydrophobic photoresist PR may be exposed, and the portion of the hydrophobic photoresist PR located in the first pattern area PA1 may be removed. For example, the portion of the hydrophobic photoresist PR located in the first pattern area PA1 may be removed by a development process or a stripping process. As a result, as illustrated in FIG. 12, the mask pattern PRM may be formed on the fifth insulating layer GI5, exposing the first pattern area PA1 and covering the region around the first pattern area PA1.

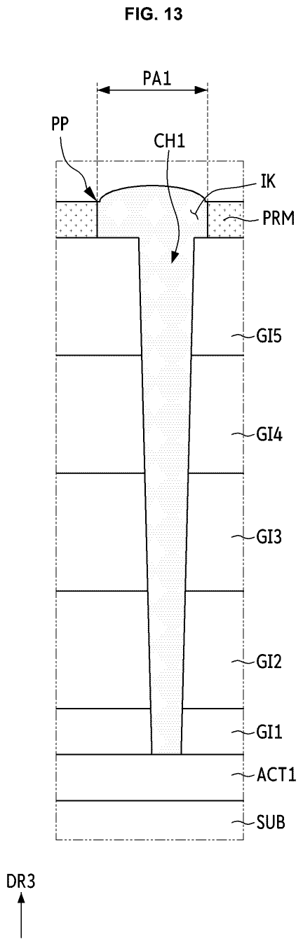

Referring to FIG. 13, inorganic ink IK containing conductive particles may be applied over the lower insulating layers and the first contact hole CH1. For example, the inorganic ink IK may be applied appropriately or easily (e.g., by dropping or coating) over the lower insulating layers and the first contact hole CH1 using an inkjet printing method or a slit coating method. The inorganic ink IK may also be applied using other methods. The inorganic ink IK may be applied individually to each pattern area, including the region where each contact hole (e.g., the first contact hole CH1) is formed, such as the first pattern area PA1, or may be applied across the entire surface over the lower insulating layers and the mask pattern PRM.

According to some embodiments, the inorganic ink IK may be metal ink containing metal particles. The type and concentration of the inorganic ink IK may be selected based on the structure, shape, or aspect ratio of each contact hole to be filled with the inorganic ink IK, including the first contact hole CH1. For example, the type and concentration of the inorganic ink IK may be determined so that each contact hole, including the first contact hole CH1, may be appropriately filled and may meet required electrical characteristics when transformed later into a conductive pattern.

In some embodiments, the mask pattern PRM formed from the hydrophobic photoresist PR may have hydrophobic properties. Accordingly, the inorganic ink IK applied to the first pattern area PA1 may flow primarily into the region uncovered by the mask pattern PRM. For example, the inorganic ink IK applied to the first pattern area PA1 and its surroundings may concentrate in the first pattern area PA1, effectively filling the first contact hole CH1.

According to some embodiments, the amount of inorganic ink IK applied may be adjusted to ensure that the contact hole exposed in each pattern area may be completely filled with the inorganic ink IK. Additionally, the amount of inorganic ink IK may be adjusted so as to be applied to an appropriate thickness or height in each pattern area. Accordingly, the first contact hole CH1 may be completely filled with the inorganic ink IK without any voids. Furthermore, the inorganic ink IK may adequately cover the upper surfaces of the lower insulating layers exposed in the first pattern area PA1 (e.g., the upper surface of the fifth insulating layer GI5 exposed in the first pattern area PA1). As the mask pattern PRM is hydrophobic, a pinning point PP may be formed between the mask pattern PRM and the inorganic ink IK, causing the inorganic ink IK in the first pattern area PA1 to take on a convex shape.

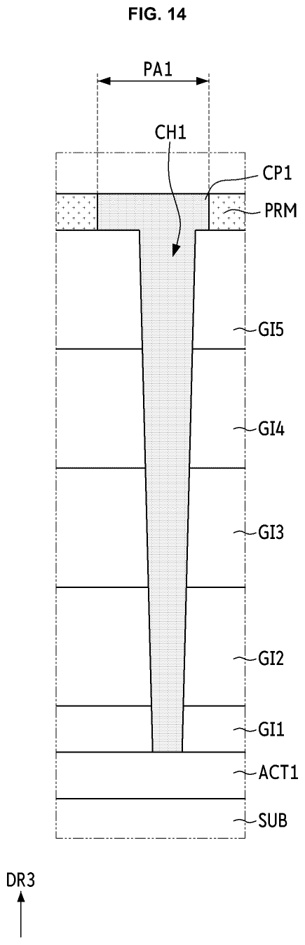

Referring to FIGS. 13 and 14, the inorganic ink IK filled in the first pattern area PA1 may be processed into the first conductive pattern CP1. For example, the solvent in the inorganic ink IK may be removed, and the inorganic ink IK in the first pattern area PA1 may be transformed into the first conductive pattern CP1 through a post-processing or thermal processing method such as curing, drying, or annealing. For example, when metal ink is used as the inorganic ink IK, the metal ink may be transformed into the first conductive pattern CP1 by curing (e.g., UV curing), drying (e.g., vacuum chamber drying or thermal curing with heat and vacuum), or sintering. In this case, the first conductive pattern CP1 may contain metal particles. According to some embodiments, when metal ink is cured using UV curing, the metal ink may contain a low-boiling-point solvent and a UV curing agent.

As the solvent in the inorganic ink IK is removed, the first conductive pattern CP1 may have a smaller volume than the inorganic ink IK and may be processed into a more concentrated form of the conductive material. For example, the first conductive pattern CP1 may be formed as a thin film with a smaller thickness than the inorganic ink IK applied in the first pattern area PA1. If metal ink is used as the inorganic ink IK, the first conductive pattern CP1 may be formed as a metal thin film containing metal particles. The density of the conductive material in the first conductive pattern CP1 may be higher than the density of the conductive material in the inorganic ink IK.

Through the processes described with reference to FIGS. 10 through 14, the first conductive pattern CP1 that fills the first contact hole CH1 may be formed in the first pattern area PA1. For example, the first conductive pattern CP1 may completely fill the first contact hole CH1 and cover the region around the first contact hole CH1 from above. According to some embodiments, during the formation of the first conductive pattern CP1 using the inorganic ink IK, the second, third, and fourth conductive patterns CP2, CP3, and CP4 may also be formed simultaneously (or concurrently) using the same material.

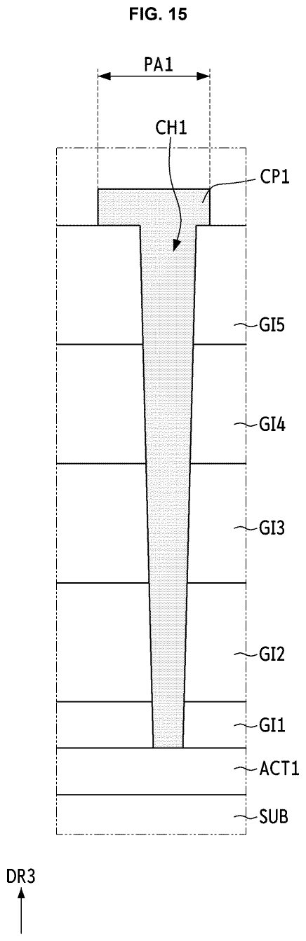

Referring to FIGS. 14 and 15, after the formation of the first conductive pattern CP1, the mask pattern PRM may be removed. For example, after forming the conductive patterns in each pattern area not covered by the mask pattern PRM, the mask pattern PRM may be removed through an ashing process.

Through the processes described above with reference to FIGS. 8 through 15, the first semiconductor layer SCL1, the first insulating layer GI1, the first conductive layer GTL1, the second insulating layer GI2, the second conductive layer GTL2, the third insulating layer, the third conductive layer GTL3, the fourth insulating layer GI4, the second semiconductor layer SCL2, and the fifth insulating layer GI5 may be formed on the substrate SUB. Additionally, on the fifth insulating layer GI5, at least one conductive pattern, including the first conductive pattern CP1 of the fourth conductive layer GTL4, may be formed.

According to some embodiments, using the inorganic ink IK containing conductive particles, some of the conductive patterns of the fourth conductive layer GTL4 (e.g., the first, second, third, and fourth conductive patterns CP1, CP2, CP3, and CP4) may be formed simultaneously (or concurrently). Additionally, other conductive patterns of the fourth conductive layer GTL4 (e.g., the second gate electrode GE2, the third gate electrode GE3, and/or at least one wiring) may be formed through an additional process (e.g., a conductive film forming process including a deposition process for a conductive material and a patterning process including an etching process for a conductive film).

According to some embodiments, all the conductive patterns of the fourth conductive layer GTL4 may be formed simultaneously (or concurrently) using the inorganic ink IK containing conductive particles. For example, the mask pattern PRM may be located on the fifth insulating layer GI5 in the shape corresponding to all the conductive patterns to be formed in the fourth conductive layer GTL4. After applying the inorganic ink IK to the pattern areas corresponding to the respective conductive patterns, the inorganic ink IK may be processed to form all the conductive patterns of the fourth conductive layer GTL4 simultaneously (or concurrently).

Therefore, by forming the sixth insulating layer GI6, the fifth conductive layer SDL1, the seventh insulating layer ILD1, the sixth conductive layer SDL2, the eighth insulating layer ILD2, the seventh conductive layer SDL3, and the ninth insulating layer VIA on the fourth conductive layer GTL4 of FIG. 3 or 4, the circuit layer CRL may be formed. The circuit layer CRL may include the via hole VH that exposes a portion of the seventh conductive pattern CP7 in each pixel region.

Thereafter, the light-emitting element layer EDL and the encapsulation layer TFEL of FIG. 3 or 4 may be sequentially formed on the circuit layer CRL. Therefore, the display device 10 according to the embodiments of FIG. 3 or 4 can be manufactured.

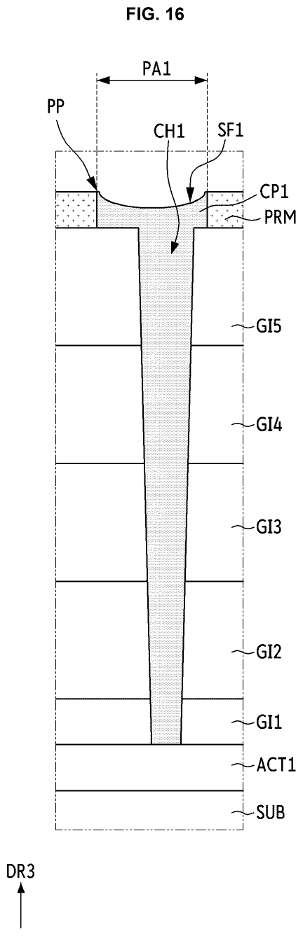

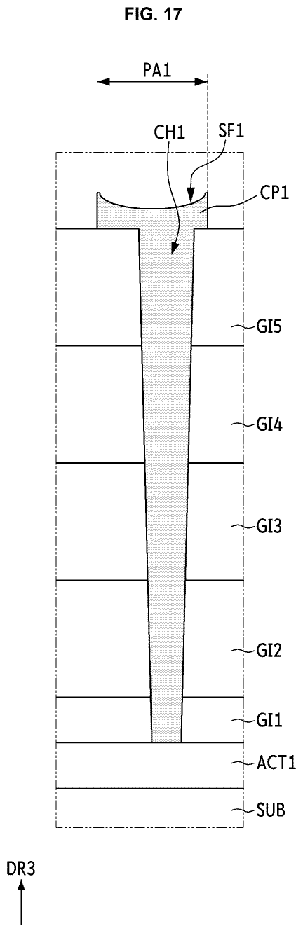

FIGS. 16 and 17 are cross-sectional views illustrating a method for manufacturing a display device according to some embodiments. For example, FIGS. 16 and 17 illustrate the step of forming a first conductive pattern CP1, particularly, how to form an upper surface SF1 of the first conductive pattern CP1 into a concave shape, as in FIG. 6.

Referring to FIGS. 13, 16, and 17, inorganic ink IK may be applied to each pattern area, including a first pattern area PA1, as illustrated in FIG. 13. During the process of transforming the inorganic ink IK into the first conductive pattern CP1, the upper surface SF1 of the first conductive pattern CP1 may be formed in a concave shape, as illustrated in FIGS. 16 and 17. For example, the inorganic ink IK, initially applied in a convex shape into the first pattern area PA1, may be transformed into the concave-shaped first conductive pattern CP1 due to the coffee-ring effect that occurs during the removal of the solvent of the inorganic ink IK. For example, the first conductive pattern CP1 may have a maximum height at a pinning point PP, where it contacts a mask pattern PRM.

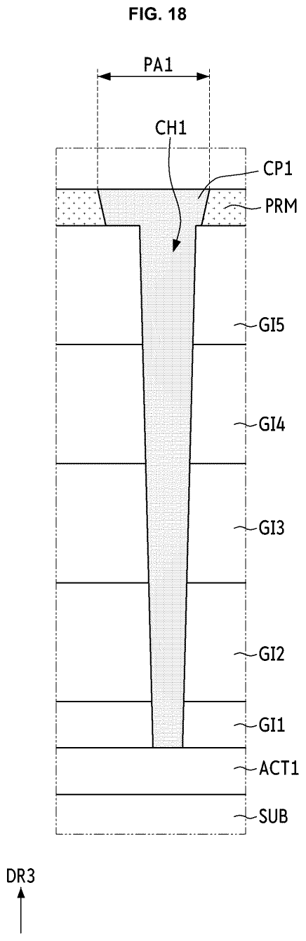

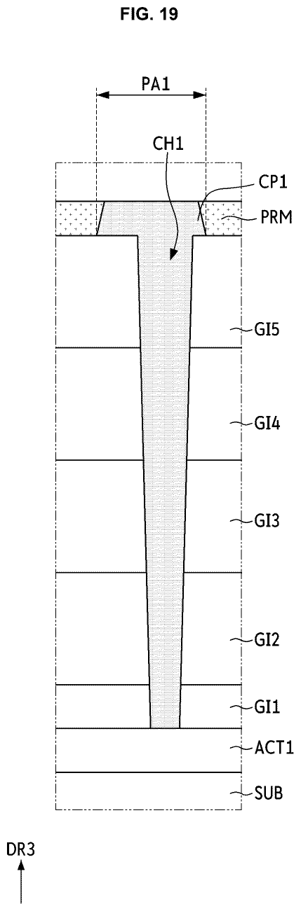

FIGS. 18 and 19 are cross-sectional views illustrating methods for manufacturing a display device according to some embodiments. For example, FIGS. 18 and 19 are cross-sectional views for explaining the step of transforming inorganic ink IK applied to a first pattern area PA1 into a first conductive pattern CP1, as in FIG. 14, and illustrate different embodiments from FIG. 14 in terms of the shape of the first conductive pattern CP1 formed from the inorganic ink IK.

Referring to FIGS. 18 and 19 in addition to FIG. 14, the first conductive pattern CP1 may have a shape corresponding to a mask pattern PRM. For example, the region where the inorganic ink IK is applied may be limited by the mask pattern PRM, and accordingly, the first conductive pattern CP1 formed from the inorganic ink IK may have the shape corresponding to the mask pattern PRM. For example, as illustrated in FIG. 14, if the mask pattern PRM includes vertical side surfaces substantially perpendicular to its lower insulating layers, such as a fifth insulating layer GI5, the first conductive pattern CP1 may include vertical side surfaces. Alternatively, as illustrated in FIGS. 15 and 16, if the mask pattern PRM has tapered or inversely tapered inclined side surfaces, the first conductive pattern CP1 may also include tapered or inversely tapered side surfaces conforming to the mask pattern PRM. According to some embodiments, the shape of the mask pattern PRM may be controlled to form the first conductive pattern CP1 in a desired shape.

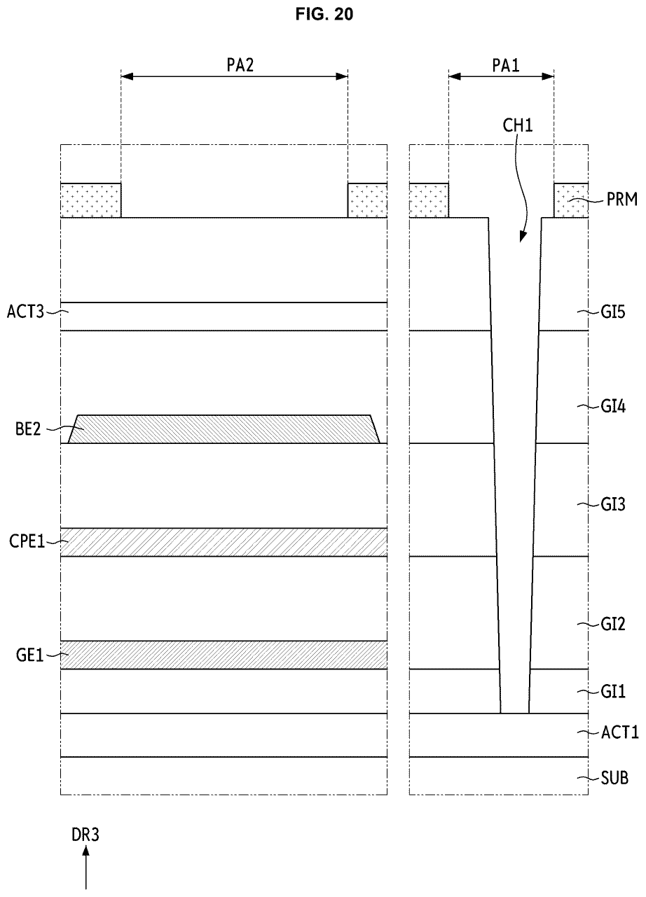

FIGS. 20 through 23 are cross-sectional views illustrating a method for manufacturing a display device according to some embodiments. For example, FIGS. 20 through 23 sequentially illustrate manufacturing processes for forming the patterns of the fourth conductive layer GTL4 during the fabrication of the display device 10 according to the embodiments of FIG. 4. FIGS. 20 through 23 illustrate portions of the display device 10 under production, corresponding to parts A1 and A2 of FIG. 4.

Referring to FIGS. 20 through 23 in addition to FIGS. 3 through 15, the first conductive pattern CP1 may be formed in the first pattern area PA1 using inorganic ink IK, and at the same time, another conductive pattern may be formed in another pattern area spaced apart from the first pattern area PA1. For example, using the inorganic ink IK, the first conductive pattern CP1 may be formed in the first pattern area PA1, and the third gate electrode GE3 may be formed in a second pattern area PA2.

For example, as illustrated in FIG. 20, the mask pattern PRM may be formed to expose the first pattern area PA1 and the second pattern area PA2, which is spaced apart from the first pattern area PA1, while covering the surroundings of the first and second pattern areas PA1 and PA2.

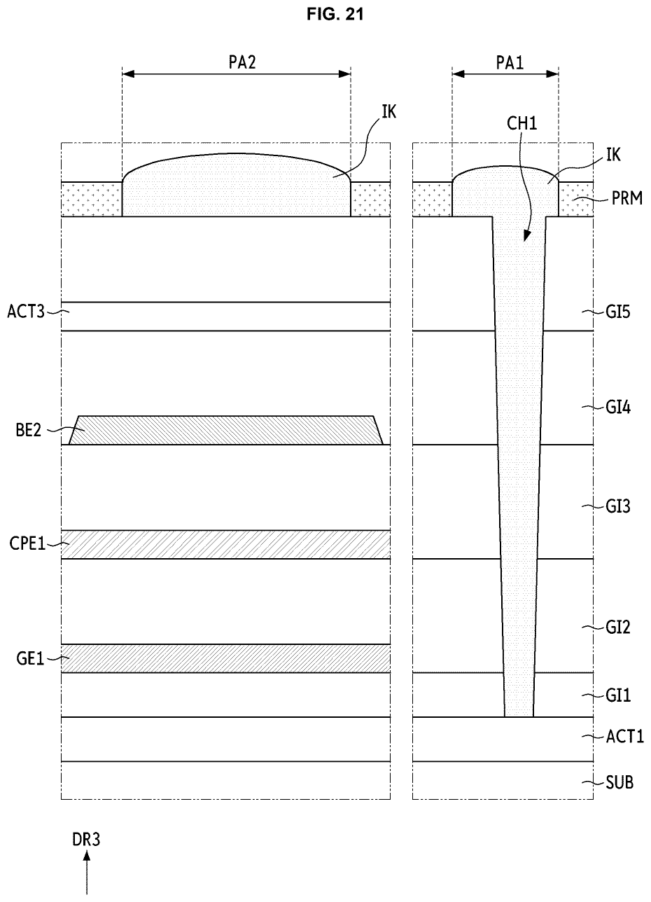

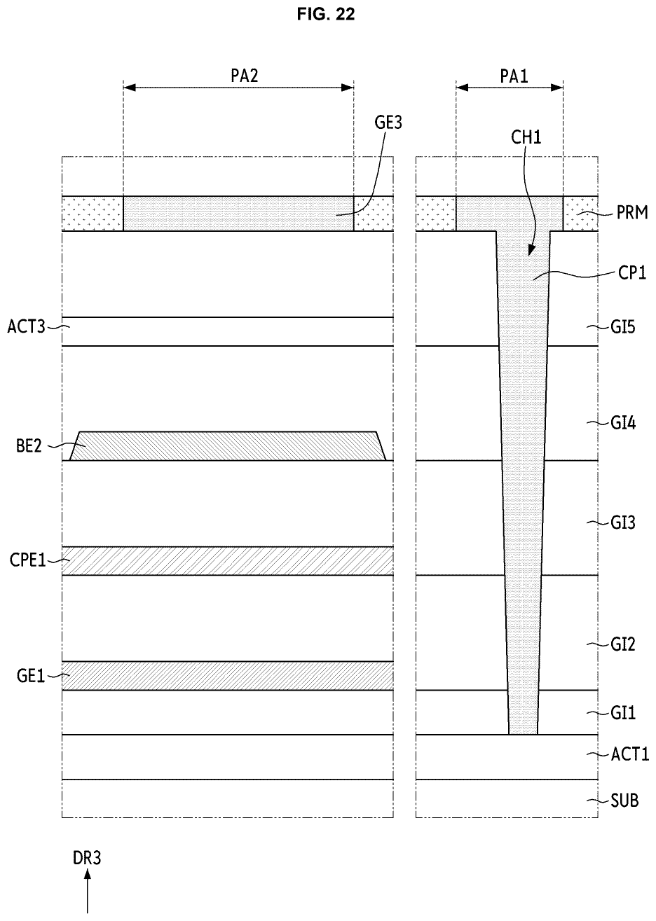

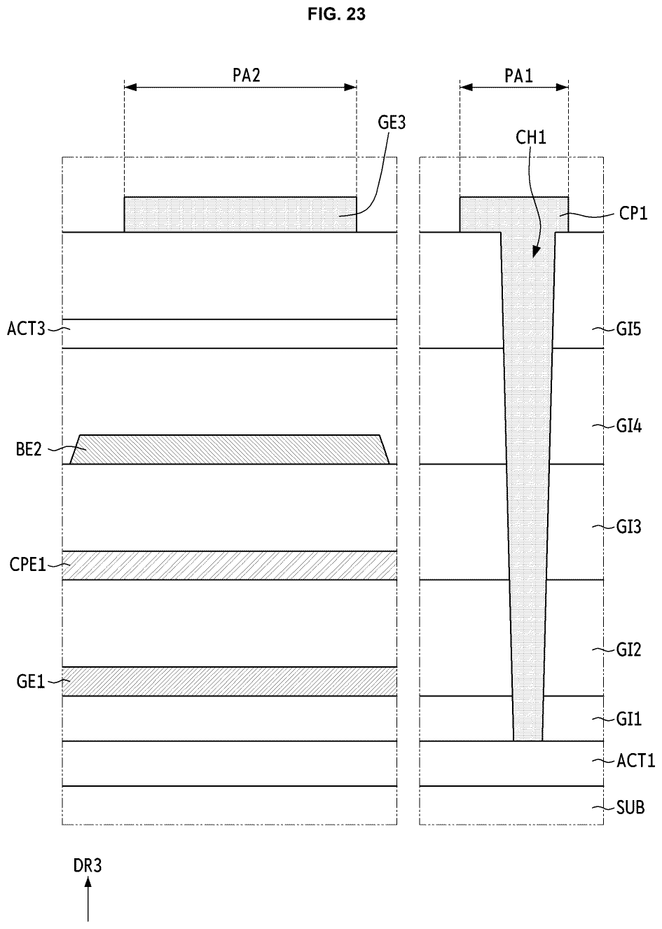

Thereafter, as illustrated in FIG. 21, the inorganic ink IK may be applied to the first and second pattern areas PA1 and PA2, and as illustrated in FIG. 22, the inorganic ink IK applied to the first and second pattern areas PA1 and PA2 may be processed into the first conductive pattern CP1 and the third gate electrode GE3, respectively. For example, the solvent in the inorganic ink IK applied to the first and second pattern areas PA1 and PA2 may be removed, and the inorganic ink IK applied to the first and second pattern areas PA1 and PA2 may be transformed into the first conductive pattern CP1 and the third gate electrode GE3, respectively. Thereafter, as illustrated in FIG. 23, the mask pattern PRM may be removed.

In this manner, using the inorganic ink IK, the first conductive pattern CP1 that fills the first contact hole CH1 may be formed, and at the same time, other conductive patterns (e.g., the second conductive pattern CP2, the third conductive pattern CP3, the fourth conductive pattern CP4, the second gate electrode GE2, the third gate electrode GE3, and at least one wiring of the fourth conductive layer GTL4) located in the same layer as the first conductive pattern CP1 may also be formed. The other conductive patterns formed simultaneously (or concurrently) with the first conductive pattern CP1 may include the conductive particles contained in the inorganic ink IK.

As described above, according to the aforementioned embodiments of the display device 10 and its manufacturing method, a conductive pattern that stably fills a contact hole can be formed using inorganic ink IK containing conductive particles. Accordingly, contact defects that may occur in the contact hole can be prevented or reduced, and the reliability of the display device 10 can be relatively improved.

According to these embodiments, even in a high-resolution display device 10 including a narrow and deep contact hole (e.g., a high aspect ratio contact hole such as the first contact hole CH1), a conductive pattern (e.g., the first conductive pattern CP1) can be stably formed inside the contact hole. For example, by covering the surroundings of the contact hole with a hydrophobic mask pattern PRM and applying inorganic ink IK to the contact hole, the contact hole can be completely filled with the inorganic ink IK without any voids. Thereafter, the inorganic ink IK can be processed or transformed into a conductive pattern that completely or stably fills the contact hole. Accordingly, the depth of the contact hole that can be filled with a single conductive pattern can be increased without the need for an intermediate bridge, and the number and/or size (e.g., width or area) of contact holes can be minimized.

Furthermore, according to the embodiments, another contact hole may be directly located on the conductive pattern to overlap with the contact hole penetrated by the conductive pattern. Accordingly, the design structure of the circuit layer CRL can be relatively improved or optimized.

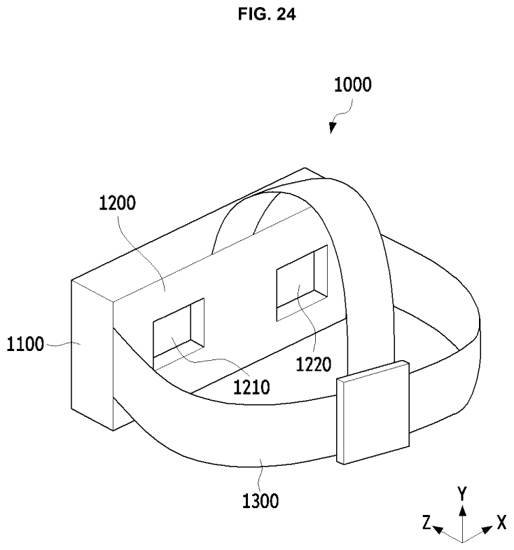

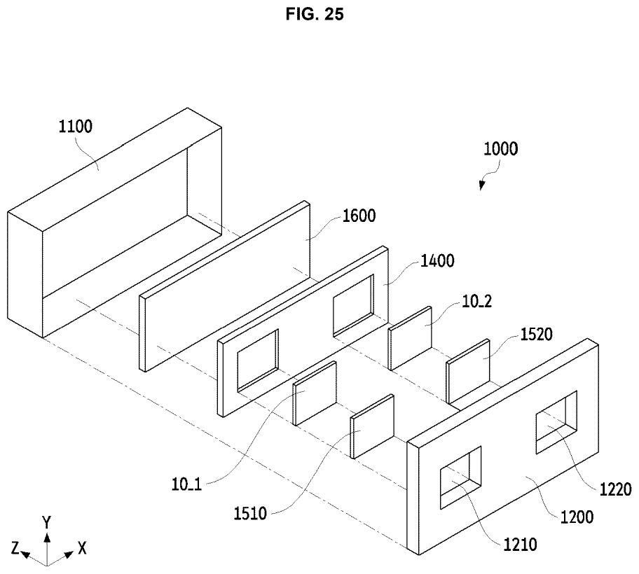

FIG. 24 is a perspective view illustrating a head-mounted display (HMD) device according to some embodiments. FIG. 25 is an exploded perspective view illustrating an example of the HMD device of FIG. 24.

Referring to FIGS. 24 and 25, an HMD device 1000 includes a first display device 10_1, a second display device 10_2, a display device housing 1100, a housing cover 1200, a first eyepiece lens 1210, a second eyepiece lens 1220, a head mounting band 1300, a middle frame 1400, a first optical member 1510, a second optical member 1520, and a control circuit board 1600.

The first display device 10_1 provides an image to a user's left eye, and the second display device 10_2 provides an image to the user's right eye. According to some embodiments, the first and second display devices 10_1 and 10_2 may each correspond to the display device 10 described with reference to FIGS. 1 through 7. Thus, descriptions of the first and second display devices 10_1 and 10_2 will be omitted.

The first optical member 1510 may be located between the first display device 10_1 and the first eyepiece lens 1210. The second optical member 1520 may be located between the second display device 10_2 and the second eyepiece lens 1220. Each of the first and second optical members 1510 and 1520 may include at least one convex lens.

The middle frame 1400 may be located between the first display device 10_1 and the control circuit board 1600, and between the second display device 10_2 and the control circuit board 1600. The middle frame 1400 serves to support and secure the first display device 10_1, the second display device 10_2, and the control circuit board 1600.

The control circuit board 1600 may be located between the middle frame 1400 and the display device housing 1100. The control circuit board 1600 may be connected to the first and second display devices 10_1 and 10_2 through connectors. The control circuit board 1600 converts a video source input from the outside into digital video data DATA and transmits the digital video data DATA to the first and second display devices 10_1 and 10_2 via the connectors.

The control circuit board 1600 may transmit digital video data DATA corresponding to an image optimized for the user's left eye to the first display device 10_1 and digital video data DATA corresponding to an image optimized for the user's right eye to the second display device 10_2. Alternatively, the control circuit board 1600 may transmit the same digital video data DATA to both the first and second display devices 10_1 and 10_2.

The display device housing 1100 serves to house the first display device 10_1, the second display device 10_2, the middle frame 1400, the first optical member 1510, the second optical member 1520, and the control circuit board 1600. The housing cover 1200 is arranged to cover the open side of the display device housing 1100. The housing cover 1200 may include the first eyepiece lens 1210, arranged for the user's left eye, and the second eyepiece lens 1220, arranged for the user's right eye. FIGS. 24 and 25 illustrate the first and second eyepiece lenses 1210 and 1220 as being separately arranged, but the present disclosure is not limited thereto. The first and second eyepiece lenses 1210 and 1220 may be combined into a single unit.

The first eyepiece lens 1210 may be aligned with the first display device 10_1 and the first optical member 1510, and the second eyepiece lens 1220 may be aligned with the second display device 10_2 and the second optical member 1520. Thus, the user may view an image from the first display device 10_1, magnified as a virtual image by the first optical member 1510, through the first eyepiece lens 1210, and view the image from the second display device 10_2, also magnified as a virtual image by the second optical member 1520, through the second eyepiece lens 1220.

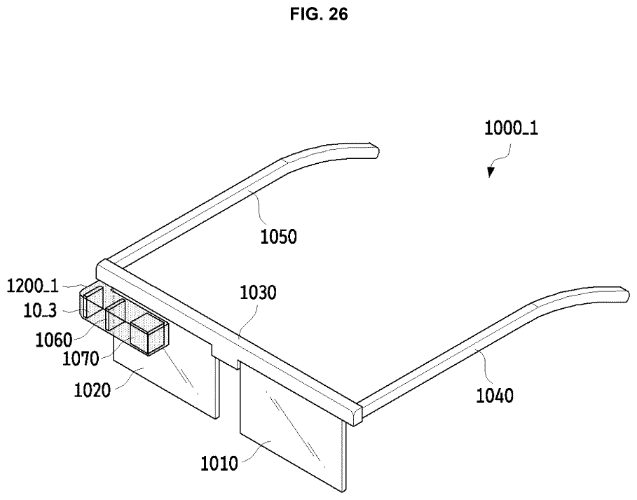

The head mounting band 1300 serves to secure the display device housing 1100 to the user's head, ensuring that the first and second eyepiece lenses 1210 and 1220 of the housing cover 1200 remain positioned in front of the user's left and right eyes, respectively. If the display device housing 1100 is designed to be lightweight and compact, the HMD device 1000 may include a pair of glasses frames, as illustrated in FIG. 26, instead of the head mounting band 1300.

In addition, the HMD device 1000 may further include a battery for supplying power, an external memory slot for storing an external memory, an external connection port, and a wireless communication module for receiving video sources. The external connection port may be a universal serial bus (USB) port, a display port, or a high- definition multimedia interface (HDMI) port, and the wireless communication module may be a 5G communication module, a 4G communication module, a Wi-Fi module, or a Bluetooth module.

FIG. 26 is a perspective view illustrating an HMD device according to some embodiments.

Referring to FIG. 26, an HMD device 1000_1 may be implemented as a glasses-type display device where a compact, lightweight display device housing 1200_1 is implemented. The HMD device 1000_1 may include a display device 10_3, a left eye lens 1010, a right eye lens 1020, a supporting frame 1030, temple arms 1040 and 1050, an optical member 1060, an optical path conversion unit 1070, and a display device housing 1200_1.

The display device housing 1200_1 may include the display device 10_3, the optical member 1060, and the optical path conversion unit 1070. According to some embodiments, the display device 10_3 may correspond to the display device 10 described above with reference to FIGS. 1 through 7. An image displayed on the display device 10_3 may be magnified by the optical member 1060, and its optical path may be converted by the optical path conversion unit 1070 to be provided to a user's right eye through the right eye lens 1020. As a result, the user can view an augmented reality (AR) image in which the virtual image displayed on the display device 10_3 is combined with the real-world image seen through the right eye lens 1020.

FIG. 26 illustrates an example where the display device housing 1200_1 is located at the right end of the supporting frame 1030, but the present disclosure is not limited thereto. Alternatively, for example, the display device housing 1200_1 may be located at the left end of the supporting frame 1030, in which case, the image from the display device 10_3 may be provided to the user's left eye. Alternatively, the display device housing 1200_1 may be located at both the left and right ends of the supporting frame 1030, allowing the user to view the image displayed on the display device 10_3 with both eyes.

In concluding the detailed description, those skilled in the art will appreciate that many variations and modifications can be made to the embodiments without substantially departing from the spirit and scope of embodiments according to the present disclosure. Therefore, the disclosed embodiments of the present disclosure are used in a generic and descriptive sense only and not for purposes of limitation.

What is claimed is:

1. A display device comprising:
a substrate; and
a circuit layer on the substrate and including a semiconductor layer and conductive layers,
wherein the circuit layer includes:
a lower pattern included in one of the semiconductor layer and the conductive layers;
a plurality of insulating layers on the lower pattern;
a first contact hole penetrating the plurality of insulating layers and exposing a portion of the lower pattern; and
a first conductive pattern on the plurality of insulating layers, filling the first contact hole, and including conductive particles.

2. The display device of claim 1, wherein the conductive particles are metal particles.

3. The display device of claim 1, wherein a height of an edge portion of the first conductive pattern is greater than a height of a central portion of the first conductive pattern.

4. The display device of claim 3, wherein an upper surface of the first conductive pattern has a shape in which the height gradually increases from the central portion to the edge portion.

5. The display device of claim 1, wherein the first conductive pattern completely fills the first contact hole.

6. The display device of claim 1, wherein an aspect ratio of the first contact hole is 0.3 or greater.

7. The display device of claim 1, wherein the circuit layer further includes a second conductive pattern in a same layer as the first conductive pattern, and
the first and second conductive patterns include a same material.

8. The display device of claim 7, wherein the circuit layer further includes a second contact hole penetrating the plurality of insulating layers below the second conductive pattern and exposing a portion of a pattern below the second conductive pattern, and
the second conductive pattern completely fills the second contact hole.

9. The display device of claim 1, wherein the circuit layer further includes an electrode in a same layer as the first conductive pattern, and the first conductive pattern and the electrode include different materials.

10. The display device of claim 9, wherein the electrode includes a metal layer.

11. The display device of claim 1, wherein the circuit layer further includes an electrode in a same layer as the first conductive pattern, and
the first conductive pattern and the electrode include a same material.

12. The display device of claim 1, wherein the circuit layer further includes:
at least one insulating layer on the first conductive pattern;
an upper contact hole penetrating the at least one insulating layer and exposing a portion of the first conductive pattern; and
an upper pattern on the at least one insulating layer and electrically connected to the first conductive pattern through the upper contact hole.

13. The display device of claim 12, wherein the first contact hole and the upper contact hole overlap in a thickness direction of the substrate.

14. The display device of claim 1, further comprising:
a light-emitting element layer on the circuit layer and including a light-emitting element electrically connected to a circuit element inside the circuit layer.

15. A method for manufacturing a display device, comprising:
forming a lower pattern including a semiconductor material or a conductive material on a substrate, and forming a plurality of insulating layers covering the lower pattern;
forming a contact hole penetrating the plurality of insulating layers and exposing a portion of the lower pattern; and
forming a conductive pattern filling the contact hole,
wherein forming the conductive pattern comprises:
forming a mask pattern that exposes a first pattern area where the conductive pattern is to be formed and covers surroundings of the first pattern area, on the plurality of insulating layers and the contact hole;
applying inorganic ink containing conductive particles to the plurality of insulating layers and the contact hole; and
processing the inorganic ink into the conductive pattern.

16. The method of claim 15, wherein forming the mask pattern comprises forming the mask pattern by a photolithography process using hydrophobic photoresist.

17. The method of claim 15, wherein applying the inorganic ink to the plurality of insulating layers and the contact hole comprises applying the inorganic ink by an inkjet printing method or a slit coating method and completely filling the contact hole with the inorganic ink.

18. The method of claim 15, further comprising:
removing the mask pattern after the forming the conductive pattern.

19. The method of claim 15, wherein the mask pattern further exposes a second pattern area spaced apart from the first pattern area and covers surroundings of the first and second pattern areas.

20. The method of claim 19, wherein
the inorganic ink is also applied to the second pattern area, and
in the processing the inorganic ink into the conductive pattern, the inorganic ink applied to the second pattern area is processed into an electrode in a same layer as the conductive pattern.
